(19) United States
(12) Patent Application Publication
(10) Pub. No.: US 2026/0369307 A1
(43) Pub. Date: Nov. 19, 2026

(54) MEMORY BLOCK AND MANUFACTURING METHOD THEREOF, AND MEMORY CELL

(71) Applicant: WUHAN XINXIN SEMICONDUCTOR MANUFACTURING CO., LTD., WUHAN (CN)

(72) Inventor: Kaiwei CAO, WUHAN (CN)

(21) Appl. No.: 19/121,102

(22) PCT Filed: Dec. 16, 2022
(86) PCT No.: PCT/CN2022/139687

§ 371 Date: Apr. 14, 2025

(30) Foreign Application Priority Data
Oct. 27, 2022 (CN) 202211343304.9

(51) Int. Cl. G11C 5/06; H10B 41/10; H10B 41/27; H10B 43/10; H10B 43/27

(52) U.S. Cl. CPC G11C 5/063; H10B 41/10; H10B 41/27; H10B 43/10; H10B 43/27

(57) ABSTRACT

The present application provides a memory block and a manufacturing method thereof, and a memory cell. The method includes: providing a semiconductor substrate including a substrate and a plurality of memory subarray layers formed on the substrate; forming a plurality of word-line holes on the semiconductor substrate to divide each memory subarray layer into a plurality of columns of drain region semiconductor strips, channel semiconductor strips, and source region semiconductor strips along a row direction; forming a storage structure on each of at least one side of a part of each word-line hole that exposes a corresponding drain region semiconductor strip, a corresponding channel semiconductor strip, and a corresponding source region semiconductor strip; filling each word-line hole with a gate material to form a plurality of gate strips.

### CROSS REFERENCE TO RELATED APPLICATIONS

The present disclosure is a 35 U.S.C. § 371 National Phase conversion of International (PCT) Patent Application No. PCT/CN2022/139687, filed on Dec. 16, 2022, which claims priority to Chinese Patent Application No. 202211343304.9, filed on Oct. 27, 2022, the entire disclosures of which are incorporated herein by reference.

### TECHNICAL FIELD

The present disclosure relates to the field of semiconductor devices, and in particular to a memory block and a manufacturing method thereof, and a memory cell.

### BACKGROUND

Two-dimensional (2D) memory blocks are prevalent in electronic devices and may include, for example, NOR-flash memory arrays, NAND-flash memory arrays, dynamic random-access memory (DRAM) arrays, etc. However, 2D memory arrays are approaching scaling limits and the storage density cannot be further increased.

### SUMMARY

To solve the above technical problems, a solution adopted by the present disclosure is to provide a manufacturing method of a memory block. The method includes: providing a semiconductor substrate, the semiconductor substrate including a substrate and a plurality of memory subarray layers formed on the substrate, the memory subarray layers being sequentially stacked along a height direction perpendicular to the substrate, and each memory subarray layer including a drain region semiconductor layer, a channel semiconductor layer, and a source region semiconductor layer stacked along the height direction; forming a plurality of word-line holes on the semiconductor substrate to divide each memory subarray layer into a plurality of columns of drain region semiconductor strips, channel semiconductor strips, and source region semiconductor strips along a row direction, the word-line holes being arranged in a matrix in the row direction and a column direction, each word-line hole extending along the height direction, and at least one side of each word-line hole exposing parts of at least one column of drain region semiconductor strips, channel semiconductor strips, and source region semiconductor strips of the memory subarray layers; forming a storage structure on each of at least one side of a part of each word-line hole that exposes a corresponding drain region semiconductor strip, a corresponding channel semiconductor strip, and a corresponding source region semiconductor strip, the storage structure being a charge trapping storage structure; filling each word-line hole with a gate material to form a plurality of gate strips, a projection of at least a part of each gate strip coinciding with a projection of a part of a corresponding channel semiconductor strip in each memory subarray layer on a projection plane, the projection plane extending along the height direction and the column direction, and a part of the gate strip, a corresponding part of the channel semiconductor strip, a part of the charge trapping storage structure interposed between the part of the gate strip and the corresponding part of the channel semiconductor strip, and a part of the drain region semiconductor strip and a part of the source region semiconductor strip adjacent to the corresponding part of the channel semiconductor strip being configured to form a memory cell.

To solve the above technical problems, another solution adopted by the present disclosure is to provide a memory block. The memory block includes: a memory array, including a plurality of memory cells distributed in a three-dimensional array, the memory array including a plurality of stacked structures distributed along a row direction, each stacked structure extending along a column direction; each stacked structure including drain region semiconductor strips, channel semiconductor strips, and source region semiconductor strips stacked along a height direction, each drain region semiconductor strip, channel semiconductor strip, and source region semiconductor strip extending along the column direction; a plurality of gate strips spaced along the column direction being arranged on each of two sides of each stacked structure, and each gate strip extending along the height direction; in the height direction, a projection of at least a part of each gate strip coinciding with a projection of a part of a corresponding channel semiconductor strip on a projection plane, and the projection plane extending along the height direction and the column direction; a part of the gate strip, a corresponding part of the channel semiconductor strip, a part of the drain region semiconductor strip adjacent to the corresponding part of the channel semiconductor strip, and a part of the source region semiconductor strip adjacent to the corresponding part of the channel semiconductor strip being configured to form a memory cell; a charge trapping storage structure being arranged between each gate strip and the drain region semiconductor strips, channel semiconductor strips, and source region semiconductor strips of the plurality of stacked structures.

To solve the above technical problems, a solution adopted by the present disclosure is to provide a memory cell. The memory cell includes: a drain region portion, a channel portion, a source region portion, and a gate portion, the drain region portion, the channel portion, and the source region portion being stacked along a height direction, and the gate portion being disposed on one side of the drain region portion, the channel portion, and the source region portion, and extending along the height direction; in the height direction, a projection of the gate portion at least partially overlapping with a projection of the channel portion on a projection plane, the projection plane extending along the height direction and an extension direction of the drain region portion, the channel portion, and the source region portion, and a charge trapping storage structure portion being arranged between the gate portion and the drain region portion, the channel portion, and the source region portion.

### BRIEF DESCRIPTION OF THE DRAWINGS

In order to more clearly illustrate the technical solutions in the embodiments of the present disclosure or in the related art, a brief introduction will be provided below for the drawings required in the embodiments. It is apparent that the drawings described herein are merely some embodiments of the present disclosure. For those skilled in the art, other drawings may also be obtained according to the drawings without inventive effort.

FIG. 1 is a sketch of a structure of a memory device according to an embodiment of the present disclosure.

FIG. 2a is a perspective structural schematic view of a memory array according to an embodiment of the present disclosure.

FIG. 2b is another perspective structural schematic view of a memory array according to an embodiment of the present disclosure.

FIG. 3 is further another perspective structural schematic view of a memory array according to an embodiment of the present disclosure.

FIG. 4 is further another perspective structural schematic view of a memory array according to an embodiment of the present disclosure.

FIG. 5 is a perspective structural schematic view of a memory cell according to an embodiment of the present disclosure.

FIG. 6 is a perspective schematic view of a structure in which of two memory cells share the same column of drain region semiconductor strip, channel semiconductor strip, and source region semiconductor strip.

FIG. 7 is a perspective structural schematic view of a memory cell according to another embodiment of the present disclosure.

FIG. 8 is a perspective structural schematic view of a memory cell according to further another embodiment of the present disclosure.

FIG. 9 is a perspective schematic view of a partial structure of a memory block according to another embodiment of the present disclosure.

FIG. 10 is a perspective structural schematic view of a memory cell according to further another embodiment of the present disclosure.

FIG. 11 is a perspective structural schematic view of a memory block according to further another embodiment of the present disclosure.

FIG. 12 is a structural schematic view of a circuit connection of part of memory cells of a memory block according to an embodiment of the present disclosure.

FIG. 13 is a schematic view of a circuitry of the memory block shown in FIG. 11.

FIG. 14 is a schematic sketch of a plan view of the memory block shown in FIG. 11.

FIG. 15 is a schematic view of a memory cell corresponding to each layer of bit lines.

FIG. 16 is a schematic view of a three-dimensional distribution of word-lines and bit lines.

FIG. 17 is a flowchart of a manufacturing method of a memory block according to an embodiment of the present disclosure.

FIG. 18 is a schematic view of structure at a specific operation of a manufacturing method of a memory block according to an embodiment of the present disclosure.

FIG. 19 is a schematic view of structure at another specific operation of a manufacturing method of a memory block according to an embodiment of the present disclosure.

FIG. 20 is a schematic view of structure at further another specific operation of a manufacturing method of a memory block according to an embodiment of the present disclosure.

FIG. 21 is a schematic view of structure at further another specific operation of a manufacturing method of a memory block according to an embodiment of the present disclosure.

FIG. 22 is a schematic view of structure at further another specific operation of a manufacturing method of a memory block according to an embodiment of the present disclosure.

FIG. 23 is a schematic view of structure at further another specific operation of a manufacturing method of a memory block according to an embodiment of the present disclosure.

FIG. 24a is a schematic view of structure at further another specific operation of a manufacturing method of a memory block according to an embodiment of the present disclosure.

FIG. 24b is a schematic view of structure at further another specific operation of a manufacturing method of a memory block according to an embodiment of the present disclosure.

FIG. 25a is a schematic view of structure at further another specific operation of a manufacturing method of a memory block according to an embodiment of the present disclosure.

FIG. 25b is a schematic view of structure at further another specific operation of a manufacturing method of a memory block according to an embodiment of the present disclosure.

FIG. 26 is a schematic view of structure at further another specific operation of a manufacturing method of a memory block according to an embodiment of the present disclosure.

FIG. 27 is a schematic view of structure at further another specific operation of a manufacturing method of a memory block according to an embodiment of the present disclosure.

### REFERENCE NUMERALS

memory block 10; memory array 1; memory subarray layer 1a; drain region semiconductor strip 11; bit line connection line 11a; channel semiconductor strip 12; well region connection line 12a; common well region line 12b; common well region lead line 12d; source region semiconductor strip 13; source connection line 13a; common source line 13b; common source lead line 13d; interlayer isolation strip 14a; second single-crystal sacrificial semiconductor layer 14; insulating isolation layer 14′; body structure 15a; protrusion 15b; support post 16; column of semiconductor strip structures 1b; gate strip 2; isolation wall 3; isolation wall hole 31; word-line hole 4; storage structure 5; first dielectric layer 51; charge-trapping layer 52; second dielectric layer 53; floating gate 54; first insulating dielectric layer 56; odd word-line 8a; even word-line 8b; word-line connection line 7; drain region portion 11′; channel portion 12′; source region portion 13′; gate portion 2′; storage structure portion 5′; substrate 81; first single-crystal sacrificial semiconductor layer 82; first hard mask layer 83; word-line opening 831; drain region semiconductor layer 11c; channel semiconductor layer 12c; source region semiconductor layer 13c.

### DETAILED DESCRIPTION

The technical solutions in embodiments of the present disclosure will be clearly and completely described below in conjunction with the accompanying drawings in the embodiments of the present disclosure, and it is obvious that the described embodiments are only a part of the embodiments of the present disclosure, but not all of them. Based on the embodiments of the present disclosure, all other embodiments obtained by those skilled in the art without creative labor fall within the protection scope of the present disclosure.

The terms “first”, “second”, and “third” in the present disclosure are intended for descriptive purposes only and are not to be construed as indicating or implying relative importance or implicitly indicating the number of indicated technical features. Therefore, a feature defined with “first”, “second”, or “third” may explicitly or implicitly include at least one such feature. In the description of the present disclosure, the terms “a plurality of” or “multiple” means at least two, e.g., two, three, etc., unless otherwise expressly and specifically limited. All directional indications (e.g., up, down, left, right, forward, backward . . . ) in the present disclosure are intended only to explain relative position relationships, movements, etc., between components in a particular posture (as shown in the accompanying drawings). If the particular posture is changed, the directional indications are changed accordingly. In addition, the terms “include” and “have”, and any variations thereof are intended to cover non-exclusive inclusion. For example, a process, method, system, product, or device including a series of steps or units is not limited to the listed steps or units, but optionally further includes steps or units not listed, or optionally further includes other steps or units inherent to the process, method, product, or device.

References herein to the term “embodiment” mean that particular features, structures, or characteristics described in conjunction with an embodiment may be included in at least one embodiment of the present disclosure. The presence of the phrase at various positions in the specification does not necessarily mean the same embodiment, nor is it a separate or alternative embodiment that is mutually exclusive with other embodiments. It is understood, both explicitly and implicitly, by those skilled in the art that the embodiments described herein may be combined with other embodiments.

The present disclosure is described in detail below in conjunction with the accompanying drawings and embodiments.

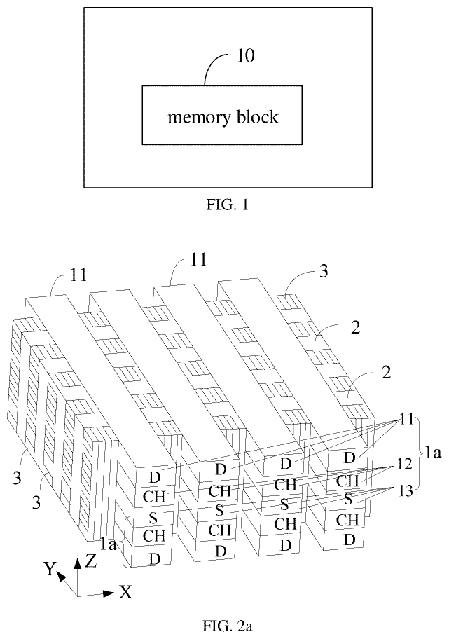

As shown in FIG. 1, FIG. 1 is a sketch of a structure of a memory device according to an embodiment of the present disclosure. A memory device is provided, which may specifically be a non-volatile memory device. The memory device may include one or more memory blocks 10. The specific structure and function of the memory block 10 may be described in connection with the memory block 10 provided in any of the following embodiments. It will be understood by those skilled in the art that a memory array 1 includes a structure in which multiple memory cells are arranged in a three-dimensional array; and the memory block 10 may include, in addition to the memory array 1 formed by the multiple memory cell arrays, other components, such as various types of wires (or connection lines), etc., enabling the memory block 10 to implement various memory operations.

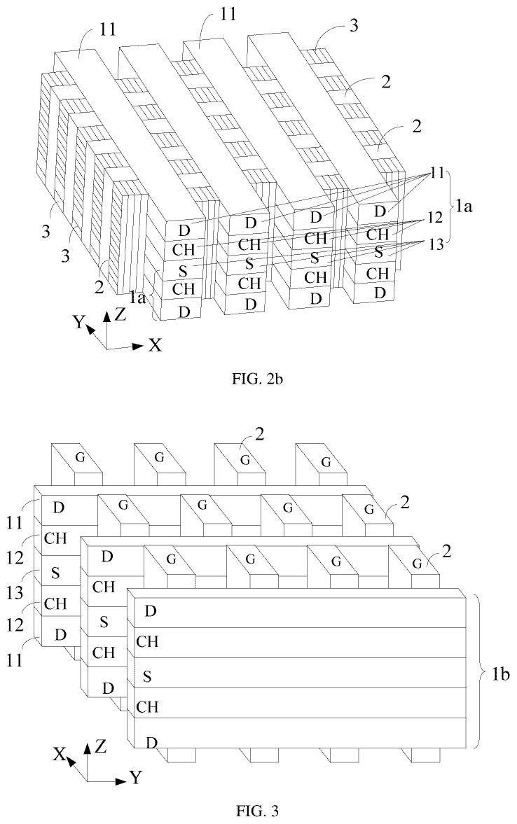

As shown in FIG. 2a to FIG. 3, FIG. 2a to FIG. 3 are perspective structural schematic views of a memory array according to an embodiment of the present disclosure. In the embodiments, a memory block 10 is provided, which includes a memory array 1. The memory array 1 includes multiple memory cells distributed in a three-dimensional array.

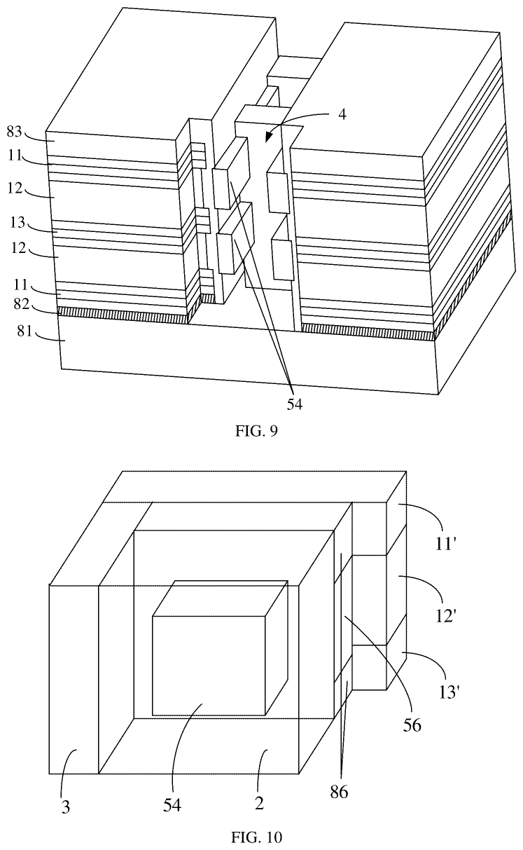

As shown in FIG. 2a, the memory array 1 includes multiple memory subarray layers 1a stacked sequentially along a height direction Z. Each memory subarray layer 1a includes a drain region semiconductor layer, a channel semiconductor layer, and a source region semiconductor layer stacked along the height direction Z. The drain region semiconductor layer, the channel semiconductor layer, and the source region semiconductor layer may each be a single-crystal semiconductor layer grown by epitaxy. The height direction Z is a direction perpendicular to a substrate (e.g., a substrate 81 shown in FIG. 9). The sequential stacking indicates a sequential arrangement on the substrate from bottom to top, and the stacking represents an arrangement and does not express or imply a structure or a top-to-bottom relationship of the layers.

In each memory subarray layer 1a, the drain region semiconductor layer (D) includes multiple drain region semiconductor strips 11 spaced along a row direction X, each drain region semiconductor strip 11 extending along a column direction Y. The channel semiconductor layer (CH) includes multiple channel semiconductor strips 12 spaced along the row direction X, each channel semiconductor strip 12 extending along the column direction Y. The source region semiconductor layer(S) includes multiple source region semiconductor strips 13 spaced along the row direction X, each source region semiconductor strip 13 extending along the column direction Y. Each drain region semiconductor strip 11, channel semiconductor strip 12, and source region semiconductor strip 13 is a single-crystal semiconductor strip, respectively. It is understood by those skilled in the art that each drain region semiconductor strip 11, channel semiconductor strip 12, and source region semiconductor strip 13 may be a single-crystal semiconductor strip formed by processing the drain region semiconductor layer, channel semiconductor layer, and source region semiconductor layer formed by epitaxy generation, respectively. As shown in FIG. 2a to FIG. 3, multiple gate strips 2 (G) are arranged on each side of each column of drain region semiconductor strips 11, channel semiconductor strips 12, and source region semiconductor strips 13, respectively. The multiple gate strips 2 distributed on a side of each column of drain region semiconductor strips 11, channel semiconductor strips 12, and source region semiconductor strips 13 are spaced along the column direction Y, and each gate strip 2 extends along the height direction Z. In this way, corresponding parts of the multiple drain region semiconductor strips 11, channel semiconductor strips 12, and source region semiconductor strips 13 in the same column in the multiple memory subarray layers 1a share the same gate strip 2.

As shown in FIG. 2b, among the multiple gate strips 2, each gate strip 2 in the same column and a corresponding gate strip 2 are staggered from each other in the column direction Y, and the corresponding gate strip 2 is in a column adjacent to the column where the gate strip 2 is located and corresponds the gate strip 2 in the row direction X. For example, each gate strip 2 in a first column and each gate strip 2 in a second column are staggered from each other in the column direction Y. Of course, as shown in FIG. 2a, each gate strip 2 in the same column and the corresponding gate strip 2 may be aligned with each other in the column direction Y, and the corresponding gate strip 2 is in a column adjacent to the column where the gate strip 2 is located and corresponds to the gate strip 2 in the row direction X. The staggered arrangement may reduce the influence on an electric field between corresponding two gate strips 2 in two adjacent columns.

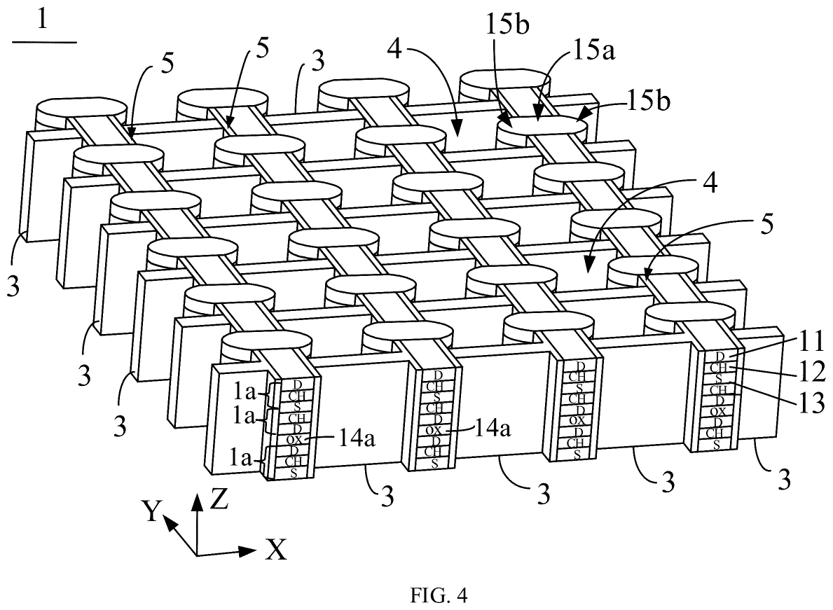

In the height direction Z, a projection of at least a part of each gate strip 2 coincides with a projection of a part of a corresponding channel semiconductor strip 12 in each memory subarray layer 1a on a projection plane. The projection plane is a plane defined by the height direction Z and the column direction Y, i.e., the projection plane extends along the height direction Z and the column direction Y. As shown in FIG. 2a to FIG. 3, for the purpose of description, it is defined that a column of drain region semiconductor strip 11, channel semiconductor strip 12, and source region semiconductor strip 13 in each memory subarray layer 1a constitutes a semiconductor strip structure; two adjacent memory subarray layers 1a may share a common source, i.e., the two adjacent memory subarray layers 1a share the same source region semiconductor layer (S). Therefore, two semiconductor strip structures corresponding to the two adjacent memory subarray layers 1a share the same source region semiconductor strip 13. Of course, it is understood by those skilled in the art that the two adjacent memory subarray layers 1a may be arranged with a non-common source design, i.e., each memory subarray layer 1a has an independent source region semiconductor layer. In this way, the two semiconductor strip structures 1b corresponding to the two adjacent memory subarray layers 1a each has its own independent source region semiconductor strip 13. In the multiple memory subarray layers 1a, the drain region semiconductor strips 11, channel semiconductor strips 12, and source region semiconductor strips 13 in the same column constitute a column of semiconductor strip structures 1b, i.e., a stacked structure 1b. The column of semiconductor strip structures 1b includes multiple semiconductor strip structures, and the number of the semiconductor strip structures in the column of semiconductor strip structures 1b is the same as the number of the memory subarray layers 1a. As shown in FIG. 2a to FIG. 3, each column of semiconductor strip structures 1b includes two semiconductor strip structures, but those skilled in the art can understand that a column of semiconductor strip structures 1b may include multiple stacked semiconductor strips. As shown in FIG. 4, which is a sketch of a perspective structure of a memory array according to another embodiment of the present disclosure, where a column of semiconductor strip structures 1b includes three semiconductor strip structures.

In other words, it is understood by those skilled in the art that the memory array 1 includes multiple stacked structures 1b distributed along the row direction X, each stacked structure 1b extending along the column direction Y. Each stacked structure 1b includes drain region semiconductor strips 11, channel semiconductor strips 12, and source region semiconductor strips 13 stacked along the height direction. Each drain region semiconductor strip 11, channel semiconductor strip 12, and source region semiconductor strip 13 extends along the column direction Y. Multiple gate strips 2 spaced along the column direction Y are arranged on each of two sides of each stacked structure 1b, and each gate strip 2 extends along the height direction Z.

A projection of a part of each column of semiconductor strip structures 1b coincides with a projection of a corresponding part of a corresponding gate strip 2 on the projection plane. In particular, a projection of a part of the channel semiconductor strip 12 in each column of semiconductor strip structures 1b coincides with a projection of a part of a corresponding gate strip 2 on the projection plane. In this way, a part of the gate strip 2, a corresponding part of the channel semiconductor strip 12, a part of the drain region semiconductor strip 11 adjacent to the corresponding part of the channel semiconductor strip 12, and a part of the source region semiconductor strip 13 adjacent to the corresponding part of the channel semiconductor strip 12are configured to form a memory cell. For example, as shown in FIG. 2a to FIG. 3, for the gate strip 2 of the first column along the row direction X and the first row along the column direction Y, a projection of a part of the gate strip 2 coincides with a projection of a corresponding part of the channel semiconductor strip 12 of the first column of the drain region semiconductor strip 11, the channel semiconductor strip 12, and the source region semiconductor strip 13 (a column of semiconductor strip structures 1b with a D/CH/S structure) of the first memory subarray layer 1a in the height direction Z. That is, the part of the gate strip 2 of the first column and the first row, the corresponding part of the first column of the channel semiconductor strip 12 of the first memory subarray layer 1a in the height direction Z, and a part of the drain region semiconductor 11 and a part of the source region semiconductor 13, that are matched with the corresponding part of the first column of the channel semiconductor strip 12 of the first memory subarray layer 1a in the height direction Z, are configured to form a memory cell.

It will be understood by those skilled in the art that, a channel is required to be formed in a semiconductor region between the semiconductor drain region and the semiconductor source region; and the gate is arranged on a side of the semiconductor region between the semiconductor drain region and the semiconductor source region for constituting a semiconductor device. Therefore, as shown in FIG. 2a to FIG. 3, the part of each gate strip 2 whose projection overlaps with the projection of a channel semiconductor strip 12 in an adjacent stacked structure 1b on the above projection plane is configured as a gate, i.e., a control gate of the corresponding memory cell; the part of the channel semiconductor strip 12 whose projection overlaps with the projection of the gate strip 2 on the above projection plane, i.e., the corresponding part of the channel semiconductor strip 12, is configured as the channel region (well region) for forming a channel therein; and the drain region semiconductor strip 11 and the source region semiconductor strip 13 adjacent to the channel semiconductor strip 12 each has a part arranged just above or below the corresponding part of the channel semiconductor strip 12, i.e., the parts of the drain region semiconductor strip 11 and the source region semiconductor strip 13 exactly match the corresponding part of the channel semiconductor strip 12 as the semiconductor drain region and the semiconductor source region. Therefore, the parts of the drain region semiconductor strip 11 and the source region semiconductor strip 13, the corresponding part of the channel semiconductor strip 12 sandwiched between the parts of the drain region semiconductor strip 11 and the source region semiconductor strip 13, cooperating with the part of the gate strip 2 as the control gate, are configured to form a memory cell.

Therefore, as shown in FIG. 2a to FIG. 3, the memory array 1 of the present disclosure is formed with multiple memory cells arranged in an array, and the multiple memory cells is comprised by the drain region semiconductor strips 11, the channel semiconductor strips 12, the source region semiconductor strips 13, and the gate strips 2. In particular, the memory array 1 of the present disclosure includes multiple memory subarray layers 1a stacked sequentially along the height direction Z. Each memory subarray layer 1a includes a layer of drain region semiconductor strips 11, a layer of channel semiconductor strips 12, a layer of source region semiconductor strips 13, and parts of gate strips 2 matching the above layers, such that each memory subarray layer 1a includes a layer of array-arranged memory cells along the height direction Z, and the stacked multiple memory subarray layers 1a constitute multiple layers of memory cells arrayed along the height direction Z.

In the present disclosure, each drain region semiconductor strip 11 is a semiconductor strip of a first doping type, such as an N-type doped semiconductor strip. In some embodiments, each drain region semiconductor strip 11 serves as a bit line (BL) of a memory block.

Each channel semiconductor strip 12 is a semiconductor strip of a second doping type, such as a P-type doped semiconductor strip. In some embodiments, each channel semiconductor strip 12 serves as a well region of a memory block.

Each source region semiconductor strip 13 is also a semiconductor strip of the first doping type, such as an N-type doped semiconductor strip. In some embodiments, each source region semiconductor strip 13 serves as a source line (SL) of the memory block.

Of course, it is understood by those skilled in the art that in other types of memory devices, each drain region semiconductor strip and each source region semiconductor strip may also be a P-type doped semiconductor strip, while each channel semiconductor strip 12 is an N-type doped semiconductor strip. The present disclosure does not limit thereto.

Referring further to FIG. 2a to FIG. 3, in the height directionZ, two adjacent memory subarray layers 1a include a drain region semiconductor layer, a channel semiconductor layer, a source region semiconductor layer, a channel semiconductor layer, and a drain region semiconductor layer stacked in sequence to share the common source region semiconductor layer. As shown in FIG. 2a to FIG. 3, the common source region semiconductor strip 13 is arranged between two adjacent channel semiconductor strips 12 in the height direction Z in the same column, and two drain region semiconductor strips 11 are arranged on two sides of the two adjacent channel semiconductor strips 12. That is, in the height direction Z, the same column of semiconductor strip structures 1b of two adjacent memory subarray layers 1a includes the drain region semiconductor strip 11, the channel semiconductor strip 12, the source region semiconductor layer 13, the channel semiconductor strip 12, and the drain region semiconductor layer 11 stacked in sequence, thereby forming two column of semiconductor strip structures 1b which share the common source region semiconductor strip 13. In this way, the storage density of the memory block 10 may be further increased while reducing cost and process.

As shown in FIG. 4, the memory array 1 includes multiple memory subarray layers 1a stacked sequentially along the height direction Z. Each memory subarray layer 1a includes a drain region semiconductor layer, a channel semiconductor layer, and a source region semiconductor layer stacked along the height direction Z.

In each memory subarray layer 1a, the drain region semiconductor layer, the channel semiconductor layer, and the source region semiconductor layer include multiple drain region semiconductor strips 11, multiple channel semiconductor strips 12, and multiple source region semiconductor strips 13, respectively, spaced along the row direction X.

Two adjacent memory subarray layers 1a include a drain region semiconductor layer, a channel semiconductor layer, a source region semiconductor layer, a channel semiconductor layer, and a drain region semiconductor layer sequentially stacked to share the same source region semiconductor layer.

An interlayer isolation layer is arranged between every two memory subarray layers 1a to isolate from the other two memory subarray layers 1a. That is, an interlayer isolation layer is arranged between each two consecutive memory subarray layers 1a and another two consecutive memory subarray layers 1a, the another two consecutive memory subarray layers 1a being adjacent to the each two consecutive memory subarray layers 1a. For example, in the height direction Z, an interlayer isolation layer is arranged between the first/second memory subarray layers 1a and the third/fourth memory subarray layers 1a; another interlayer isolation layer is arranged between the third/fourth memory subarray layer 1a and the fifth/sixth memory subarray layer 1a, and so on. It is understood that the one interlayer isolation layer is disposed between the second memory subarray layer 1a and the third memory subarray layer 1a; and the other interlayer isolation layer is disposed between the fourth memory subarray layer 1a and the fifth memory subarray layer 1a.

Specifically, as shown in FIG. 4, one interlayer isolation strip 14a is arranged between every two adjacent columns of semiconductor strip structures 1b in the same column of semiconductor strip structures 1b in the height direction Z. Similarly, an interlayer isolation strip 14a is arranged between every two adjacent columns of semiconductor strip structures 1b in another column of semiconductor strip structures 1b. It is understood by those skilled in the art that multiple interlayer isolation strips 14a in the same horizontal plane constitute an interlayer isolation layer to isolate from the semiconductor strip structures 1b in the other two memory subarray layers 1a.

In other words, in the present disclosure, each stacked structure 1b′ may include multiple stacked substructures, and each stacked substructure includes a drain region semiconductor strip 11, a channel semiconductor strip 12, a source region semiconductor strip 13, a channel semiconductor strip 12, and a drain region semiconductor strip 11 stacked sequentially along the height direction Z, thereby sharing the same source region semiconductor strip 13. In the stacked structure 1b′, an interlayer isolation strip 14a is arranged between two adjacent stacked substructures to isolate them from each other. That is, in two adjacent memory subarray layers 1a, the drain region semiconductor strip 11, channel semiconductor strip 12, source region semiconductor strip 13, channel semiconductor strip 12, and drain region semiconductor strip 11 in the same column form a stacked substructure, such that two adjacent memory subarray layers 1a share a common source region semiconductor strip 13.

Referring further to FIG. 4 or FIG. 2a, multiple isolation walls 3 are distributed in the memory array 1, and the multiple isolation walls 3 are arranged in a matrix in the row direction X and the column direction Y. As shown in FIG. 2a, multiple isolation walls 3 distributed along the column direction Y are arranged on each of two sides of each column of semiconductor strip structures 1b. Each isolation wall 3 extends along the height direction Z and the row direction X to separate at least parts of two adjacent columns of drain region semiconductor strips 11, channel semiconductor strips 12, and source region semiconductor strips 13. That is, the multiple isolation walls 3 distributed along the column direction Y are arranged on each of the two sides of each stacked structure 1b′ to separate at least parts of the two adjacent columns of stacked structures 1b′. In some embodiments, particularly during the manufacturing process of the memory block 10, the isolation walls 3 may further serve as support structures that may support two adjacent columns of the stacked structures 1b′ during and/or after the manufacturing process. In addition, a part of each side of each stacked structure 1b′ may be arranged with support posts (not shown and described in detail below), respectively, to support the two adjacent columns of the stacked structures 1b′ during and/or after the manufacturing process of the memory array 1.

A region between two adjacent isolation walls 3 in the same column in the column direction Y is configured to form a word-line hole 4. That is, any two adjacent isolation walls 3 in the same column, cooperating with two columns of semiconductor strip structures 1b (i.e., stacked structures 1b′) on both sides thereof, may form multiple regions for the word-line holes 4, and these regions may be processed such that corresponding word-line holes 4 may be formed. That is, the multiple columns of drain region semiconductor strips 11, channel semiconductor strips 12, and source region semiconductor strips 13 extending along the column direction Y pass through the multiple rows of isolation walls 3 extending along the row direction X, to form the multiple word-line holes 4 cooperating with the multiple isolation walls 3. Each word-line hole 4 extends along the height direction Z.

Each word-line hole 4 is configured to fill a gate material to form a corresponding gate strip 2. That is, a gate strip 2 is filled between two adjacent isolation walls 3 in the same column direction Y.

As shown in FIG. 5, FIG. 5 is a perspective structural schematic view of a memory cell according to an embodiment of the present disclosure. As shown in FIG. 5, the memory cell includes a drain region portion 11′, a channel portion 12′, a source region portion 13′, and a gate portion 2′. The drain region portion 11′, the channel portion 12′, and the source region portion 13′ are stacked along the height direction Z, respectively. The channel portion 12′ is disposed between the drain region portion 11′ and the source region portion 13′. The gate portion 2′ is disposed on a side of the drain region portion 11′, the channel portion 12′, and the source region portion 13′. The drain region portion 11′, the channel portion 12′, and the source region portion 13′ are each a single-crystal semiconductor.

In addition, a projection of the gate portion 2′ at least partially coincides with a projection of the channel portion 12′ on a projection plane in the height direction Z. The projection plane is located on a side of the drain region portion 11′, the channel portion 12′, and the source region portion 13′, and extends along the height direction Z and the column direction Y.

As shown in FIG. 5, it is easily understood by those skilled in the art that the drain region portion 11′ is a part of one of the drain region semiconductor strips 11 shown in FIG. 2a to FIG. 4, the channel portion 12′ is a part of one of the channel semiconductor strips 12 shown in FIG. 2a to FIG. 4, and the source region portion 13′ is a part of one of the source region semiconductor strips shown in FIG. 2a to FIG. 4. Therefore, in the height directionZ, the multiple memory subarray layers 1a includes multiple memory cells.

In addition, as shown in FIG. 5, a storage structure portion 5′ is arranged between the gate portion 2′ and the drain region portion 11′, the channel portion 12′, and the source region portion 13′. The storage structure portion 5′ may be configured to store electric charges; the gate portion 2′, the drain region portion 11′, the channel portion 12′, the source region portion 13′, and the storage structure portion 5′ sandwiched between the gate portion 2′ and the channel portion 12′, constitutes a memory cell. The memory cell may indicate logical data 1 or logical data 0 by a state of storing or not storing electric charges in the storage structure portion 5′, thereby enabling storage of data. The storage structure portion 5′ may include a charge trapping storage structure portion, a floating gate storage structure portion, or other types of capacitive storage structure portions.

Therefore, it will be understood by those skilled in the art that in the memory array 1 shown in FIG. 2a to FIG. 4, a storage structure 5 is also arranged between the gate strip 2 and the drain region semiconductor strip 11, the channel semiconductor strip 12, and the source region semiconductor strip 13, such that each memory cell can store electric charges by its corresponding storage structure portion 5′.

In addition, it should be noted that for the convenience of the accompanying drawings showing the storage structure portion 5′, the drain region portion 11′, the channel portion 12′, the source region portion 13′, the gate portion 2′, and the storage structure portion 5 shown in FIG. 5′ are shown for illustrative purposes only and do not represent actual dimensions or proportions.

It will be understood by those skilled in the art that, as above, the part of the gate strip 2 whose projection coincides with the projection of the adjacent channel semiconductor strip 12 on the above projection plane is configured as the control gate of the memory cell, such that the part of the gate strip 2 as the gate portion 2′ is the part whose projection coincides with the projection of the channel semiconductor 12 on the projection plane; the part of the channel semiconductor strip 12 whose projection coincides with the projection of the gate strip 2 on the above projection plane is the corresponding part of the channel semiconductor strip 12 as the well region, such that the part of the channel semiconductor strip 12 as the channel portion 12′ is the part of the channel semiconductor strip 12 whose projection coincides with the projection of the gate strip 2 on the projection plane; the parts of the drain region semiconductor strip 11 and the source region semiconductor strip 13 as the drain region portion 11′ and the source region portion 13′, i.e., the part of the drain region semiconductor strip 11 or the source region semiconductor strip 13 arranged above or below the channel portion 12′, are configured as the semiconductor drain region and the semiconductor source region, respectively.

Similarly, the storage structure portion 5′ is a part of the storage structure 5 disposed between the channel portion 12′ and the gate portion 2′.

Referring further to FIG. 2a to FIG. 4, a gate strip 2 is flanked by two adjacent columns of drain region semiconductor strips 11, channel semiconductor strips 12, and source region semiconductor strips 13. Therefore, these two adjacent columns of drain region semiconductor strips 11, channel semiconductor strips 12, and source region semiconductor strips 13 share the same gate strip 2. That is, for a gate strip 2, in a memory subarray layer 1a, the gate strip cooperates with corresponding parts of the drain region semiconductor strip 11, channel semiconductor strip 12, and source region semiconductor strip 13 on the left side of the gate strip 2 to form a memory cell, and cooperates with corresponding parts of the drain region semiconductor strip 11, channel semiconductor strip 12, and source region semiconductor strip 13 on the right side of the gate strip 2 to form another memory cell. In other words, in the same row, two gate strips 2 are arranged on the left and right sides of one column of drain region semiconductor strip 11, channel semiconductor strip 12, and source region semiconductor strip 13 in one memory subarray layer 1a. In this way, the one column of drain region semiconductor strip 11, channel semiconductor strip 12, and source region semiconductor strip 13 cooperates with a part of the gate strip 2 on the left side to constitute a memory cell, and cooperates with a part of the gate strip 2 on the right side to constitute another memory cell. That is, in the same row, a column of drain region semiconductor strip 11, channel semiconductor strip 12, and source region semiconductor strip 13 in one memory subarray layer 1a is shared by two gate strips 2 on its left and right sides.

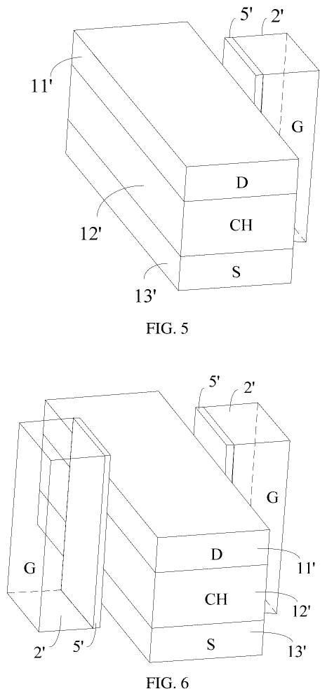

Specifically, further referring to FIG. 6, FIG. 6 is a perspective schematic view of a structure in which of two memory cells share the same column of drain region semiconductor strip, channel semiconductor strip, and source region semiconductor strip. As shown in FIG. 6, the source region portion 13′, channel portion 12′, and drain region portion 11′ stacked along the height direction Z′ cooperate with the gate portion 2′ on the left side and the storage structure portion 5′ between them to constitute a memory cell; similarly, the drain region portion 11′, the channel portion 12′, and the source region portion 13′ cooperate with the gate portion 2′ on the right side and the storage structure portion 5′ between them to constitute another memory cell. In this way, both the two memory cells share the same drain region portion 11′, channel portion 12′, and the source region portion 13′.

For ease of understanding, it may be considered that the drain region portion 11′, the channel portion 12′, and the source region portion 13′ cooperate with the gate portion 2′ on the left side and the storage structure portion 5′ between them to form a memory cell (bit); the drain region portion 11′, the channel portion 12′, and the source region portion 13′ cooperate with the gate portion 2′ on the right side and the storage structure portion 5′ between them to form another memory cell (bit).

Therefore, returning to FIG. 2a to FIG. 4, it will be understood by those skilled in the art that a storage structure 5 is first arranged on each of the left and right sides in each word-line hole 4, and the gate material is filled in the word-line hole 4 to form the gate strip 2. That is, the two adjacent columns of drain region semiconductor strips 11, channel semiconductor strips 12, and source region semiconductor strips 13 in conjunction with the storage structures 5 share the same gate strip 2.

In conjunction with FIG. 2a to FIG. 3, FIG. 5 and FIG. 6, in some embodiments, each of the above drain region semiconductor strip 11, channel semiconductor strip 12, and source region semiconductor strip 13 is a standard strip structure. That is, each drain region semiconductor strip 11, channel semiconductor strip 12, and source region semiconductor strip 13 has a standard rectangular cross-section at each position along the respective extension direction. The memory cell corresponding to the embodiments may be illustrated specifically in FIG. 5 and FIG. 6.

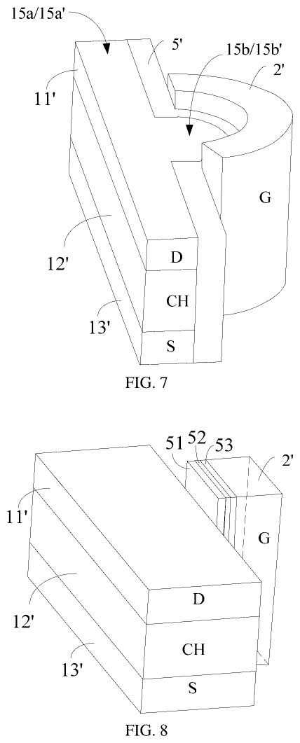

In other embodiments, in conjunction with FIG. 4 and FIG. 7, FIG. 7 is a perspective structural schematic view of a memory cell according to another embodiment of the present disclosure. Each drain region semiconductor strip 11, channel semiconductor strip 12, and source region semiconductor strip 13 includes a body structure 15a and multiple protrusions 15b, respectively. The body structure 15a extends along the column direction Y and is in the shape of a strip. The multiple protrusions 15b are distributed on both sides of the body structure in two columns, and each column includes multiple protrusions 15b spaced apart, each protrusion 15b extending from the body structure 15a in the row direction X toward a corresponding gate strip 2 (word-line hole 4) in a direction deviating from the body structure 15a. In other words, in each column of drain region semiconductor strips 11, channel semiconductor strips 12, and source region semiconductor strips 13, two columns of protrusions 15b extend from the strip-shaped body structure 15a toward the gate strips 2 (word-line holes 4) on each side. Therefore, it is understood by those skilled in the art that a surface of the storage structure 5 formed in the word-line hole 4 and a surface of the gate strip 2 near the drain region semiconductor strip 11, the channel semiconductor strip 12, and the source region semiconductor strip 13 are curved concave surfaces.

As shown in FIG. 7, for each memory cell, the drain region portion 11′, the channel portion 12′, and the source region portion 13′ include a body portion 15a′ and a protrusion portion 15b′, and each of the storage structure portion 5′ and the gate portion 2′ includes a concave surface corresponding to the protrusion portion 15b′ to wrap a surface of the protrusion 15b away from the body structure 15a.

In the present disclosure, by making each drain region semiconductor strip 11, channel semiconductor strip 12, and source region semiconductor strip 13 include multiple protrusions 15b that are raised toward the two sides, it is possible to increase the surface area of each drain region semiconductor strip 11, channel semiconductor strip 12, and source region semiconductor strip 13, thereby increasing the area of a corresponding region of the channel portion 12′ and the gate portion 2′ in each memory cell, thereby enhancing the performance of the memory block 10.

Specifically, the convex surface of the protrusion 15b away from the body structure 15a may be an arc or other form of convex surface, where the arc may include a columnar semicircular surface. The protrusions 15b of each column of drain region semiconductor strip 11, channel semiconductor strip 12, and source region semiconductor strip 13 form a columnar semicircle. The gate strip 2 corresponding to the protrusions 15b is arranged with a concave surface toward the drain region semiconductor strip 11, the channel semiconductor strip 12, and the source region semiconductor strip 13, and the concave surface is a curved surface corresponding to the convex surface of the protrusions 15b to ensure that the gate strip 2 matches the channel semiconductor strip 12 at the corresponding position.

In some embodiments, as shown in FIG. 4, the storage structure 5 extends inside the word-line hole 4 in the height direction Z and is arranged between the gate strip 2 and the adjacent drain region semiconductor strip 11, the channel semiconductor strip 12, and the source region semiconductor strip 13, such that the storage structures 5 may form the multiple memory cells together with the parts of the drain region semiconductor strips 11, the channel semiconductor strips 12, and the source region semiconductor strips 13 at corresponding positions. In the present disclosure, the storage structure 5 may be a charge trapping storage structure, a floating gate storage structure, or other types of capacitive dielectric structures.

As shown in FIG. 8, FIG. 8 is a perspective structural schematic view of a memory cell according to further another embodiment of the present disclosure. In the embodiments, the storage structure 5 is a charge trapping storage structure. As shown in FIG. 8, the storage structure portion 5′ of the memory cell includes a first dielectric portion 51, a charge-trapping portion 52, and a second dielectric portion 53. The first dielectric portion 51 is disposed between the charge-trapping portion 52 and the stacked drain region portion 11′, the channel portion 12′, and the source region portion 13′; the charge-trapping portion 52 is disposed between the first dielectric portion 51 and the second dielectric portion 53; and the second dielectric portion 53 is disposed between the charge-trapping portion 52 and the gate portion 2′. The charge-trapping portion 52 is configured to store electrical charges to enable the memory cell to store data.

Therefore, with reference to FIG. 8, it will be understood by those skilled in the art that the storage structure 5 in the memory array shown in FIG. 2a to FIG. 4 of the present disclosure includes a first dielectric layer, a charge-trapping layer, and a second dielectric layer, the first dielectric layer being disposed between the charge-trapping layer and the drain region semiconductor strip 11, the channel semiconductor strip 12, and the source region semiconductor strip 13, the charge-trapping layer being disposed between the first dielectric layer and the second dielectric layer, and the second dielectric layer being disposed between the charge-trapping layer and the gate strip 2.

The first dielectric layer (first dielectric portion 51) and the second dielectric layer (second dielectric portion 53) may be made of an insulating material, such as silicon oxide. The charge-trapping layer (charge-trapping portion 52) may be made of a storage material with charge trapping properties, in particular, the charge-trapping layer may be made of silicon nitride. Therefore, the first dielectric layer (first dielectric portion 51), the charge-trapping layer (charge-trapping portion 52), and the second dielectric layer (second dielectric portion 53) form an ONO storage structure. Specifically, reference thereto may be made to a manufacturing method involving a memory block of a charge trapping storage structure in the following embodiments.

In other embodiments, referring to FIG. 9, FIG. 9 is a perspective schematic view of a partial structure of a memory block 10 according to another embodiment of the present disclosure. In the embodiments, the storage structure 5 is a floating gate storage structure, and the floating gate storage structure extends at least partially within the word-line hole 4 in the height direction Z and is arranged between the gate strip 2 and the drain region semiconductor strip 11, the channel semiconductor strip 12, and the source region semiconductor strip 13.

Specifically, in conjunction with FIG. 9 and FIG. 10, FIG. 10 is a perspective structural schematic view of a memory cell according to further another embodiment of the present disclosure. For each memory cell, the floating gate storage structure includes multiple floating gates 54 and an insulating dielectric wrapping each floating gate 54. As shown in FIG. 9, as can be seen through the word-line hole 4, the multiple floating gates 54 are spaced along the height direction Z, and each floating gate 54 is arranged on a side of the channel semiconductor strip 12 along the row direction X and faces a corresponding part of the channel semiconductor strip 12. As shown in FIG. 10, the insulating dielectric wrapping the floating gate 54 includes a first insulating dielectric layer 56 between the channel semiconductor strip 12 and the floating gate 54, and a second insulating dielectric layer covering several other faces of the floating gate 54. That is, the insulating dielectric is present between the floating gate 54 and the corresponding part of the channel semiconductor strip 12, between two adjacent floating gates 54, and between the floating gate 54 and the gate strip 2. The insulating dielectric wraps every surface of the floating gate 54 to completely isolate the floating gate 54 from the rest of the structure.

Among them, the floating gate 54 may be made of polycrystalline silicon. The insulating dielectric may be made of an insulating material such as silicon oxide. Specifically, reference thereto may be made to a manufacturing method involving a memory block of a floating gate storage structure in the following embodiments.

In the memory cell of the charge trapping storage structure shown in FIG. 8 and FIG. 2a to FIG. 4, the storage structure 5 is adopted with a first dielectric layer (first dielectric portion 51), a charge-trapping layer (charge-trapping portion 52), and a second dielectric layer (second dielectric portion 53) to form an ONO storage structure.

The ONO storage structure is characterized by the fact that the charges injected into can be fixed near an injection point, while the floating gate storage structure (e.g., FIG. 9 to FIG. 11 is adopted with polysilicon as a floating gate) is characterized by the fact that the charges injected into can be uniformly distributed in over the entire floating gate 54. In other words, in the ONO storage structure, the charges can only move in the injection/removal direction, i.e., the stored charges can only be fixed near the injection point and cannot move arbitrarily in the charge-trapping layer, especially cannot move in the extension direction of the charge-trapping layer. Therefore, for the ONO storage structure, the charge-trapping layer only needs to have an insulating dielectric on its front and back side, and the charges stored in each memory cell will be fixed near the injection point of the charge-trapping portion 52 and will not move along the same layer of the charge-trapping layer to the charge-trapping portion 52 in another memory cell. While in the floating gate storage structure, the charge can not only move in the injection/removal direction, but also can move arbitrarily in the floating gate 54. Therefore, when the floating gate 54 is a continuous structure, the stored charges can move in the direction of extension of the floating gate 54 and thus move to the floating gate 54 in another memory cell. Therefore, for the floating gate storage structure, the floating gates 54 of each memory cell are independent, and each surface of each floating gate needs to be covered by an insulating dielectric, and need to be isolated from each other, to prevent the charges stored in the floating gates 54 in one memory cell from moving to the floating gates 54 in the other memory cells.

That is, for the memory cell and memory block of the charge trapping storage structure shown in FIG. 8 and FIG. 2a to FIG. 4, the storage structure 5 may extend from top to bottom in the word-line hole 4, and it is sufficient to arrange a first dielectric layer and a second dielectric layer on both sides of the charge-trapping layer, respectively.

In contrast, in the floating gate storage structure shown in FIG. 9 to FIG. 11, the floating gates 54 of each memory cell are independent, and each surface of each floating gate 54 needs to be covered by an insulating dielectric, and need to be isolated from each other, to prevent the charges stored in the floating gates 54 in one memory cell from moving to the floating gates in other memory cells.

It will be understood by those skilled in the art that some parts of the insulating dielectric are interconnected with each other, as long as it is possible to ensure that the floating gates 54 of each memory cell are independent of each other and that the surfaces of each floating gate 54 are wrapped with the insulating dielectric. Therefore, parts of the insulating dielectric that wraps the floating gates 54 in the word-line hole 4 may extend substantially in the height direction, thereby wrapping the floating gates 54 of each memory cell. Specifically, reference to the memory block 10 with a floating gate storage structure may be made to a manufacturing method involving a memory block of a floating gate storage structure in the following embodiments.

In addition, it will be understood by those skilled in the art that the storage structure 5 may be adopted with other types of storage structures, such as ferroelectric, variable resistance, or other types of capacitive storage structures.

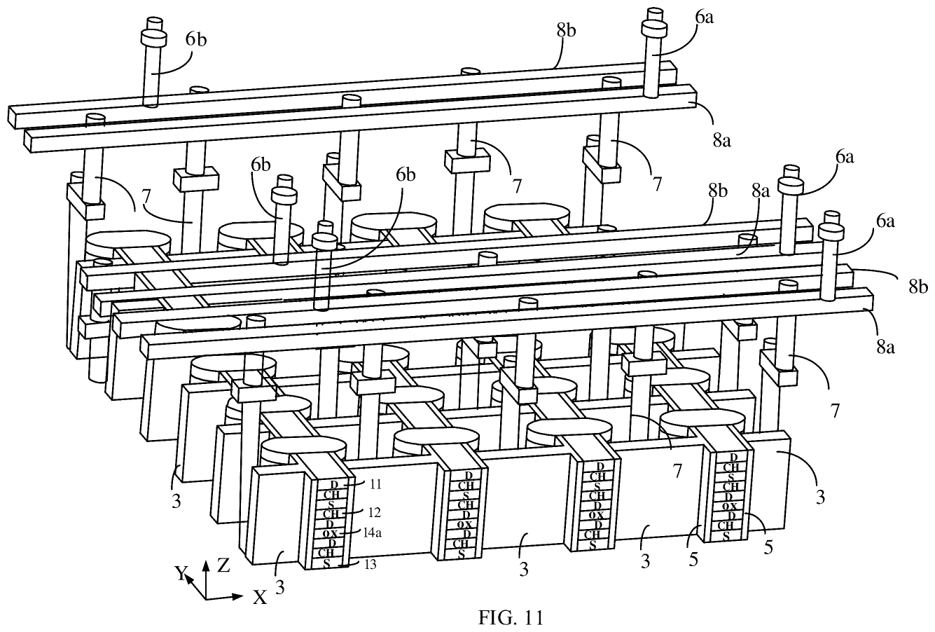

In some embodiments, referring to FIG. 11, FIG. 11 is a perspective structural schematic view of a memory block 10 according to further another embodiment of the present disclosure. In FIG. 11, only three layers of memory subarray layers 1a are shown, which are merely schematic, and it will be understood by those skilled in the art that the memory block 10 includes multiple layers of memory subarray layers 1a, with each two layers of memory subarray layers 1a separated from each other by an interlayer isolation layer (formed by multiple interlayer isolation strips 14a). The memory block 10 further includes multiple word-lines (WL) and multiple word-line connection lines 7.

As above, the part of the gate strip 2 whose projection overlaps with the projection of the channel semiconductor strip 12 in an adjacent stacked structures 1b′ on the above projection plane is configured as the control gate of the corresponding memory cell. Therefore, each gate strip 2 is configured to form the control gate (CG) of multiple memory cells. As is known, the control gates of a row of memory cells need to be connected to a corresponding word-line, through which a voltage is applied to the control gates of the row of the memory cells, thereby controlling the memory cells to perform various memory operations.

In the present disclosure, as shown in FIG. 11, multiple word-lines are arranged on top of multiple memory subarray layers 1a and are spaced apart in the column direction Y, with each word-line extending along the row direction X. Each word-line is connected to multiple word-line connection lines 7. The multiple word-line connection lines 7 connected to the same word-line extend along the height direction Z, respectively, and extend to the gate strips 2 in the multiple word-line holes 4 in the same row, respectively, to be connected to the gate strips 2 in the corresponding word-line holes 4, thereby realizing the connection of the word-line to the control gates of the multiple memory cells in the same row of the multiple memory subarray layers 1a. It can be understood that the multiple word-line holes 4 and the multiple word-line connection lines 7 are arranged in a one-to-one correspondence.

Specifically, the word-line of the same row may be an individual word-line connected to the gate strip 2 in each word-line hole 4 of the same row. Of course, the word-line of the same row may include multiple different types of word-lines; the gate strips 2 in multiple word-line holes 4 of the same row may each be connected to the multiple different types of word-lines of the corresponding row. In some embodiments, as shown in FIG. 11, multiple gate strips 2 in the same row are configured to be connected to two corresponding word-lines, i.e., each row of word-lines include an odd word-line 8a and an even word-line 8b. It should be noted that one odd word-line 8a and one even word-line 8b connected to the multiple gate strips 2 of the same row in the present disclosure are defined as one row of word-line corresponding to one row of gate strips 2.

Specifically, the memory cells of the same row in the multiple memory subarray layers 1a are connected to the odd word-line 8a of the corresponding row through the odd word-line holes 4 of the same row, respectively; the others of the memory cells of the same row in the multiple memory subarray layers 1a are connected to the even word-line 8b of the corresponding row through the even word-line holes 4 of the same row, respectively. For example, a first part of the memory cells of the first row are connected to the odd word-line 8a of the first row through the first word-line hole 4, the third word-line hole 4, the fifth word-line hole 4 . . . respectively; a second part of the memory cells of the first row are connected to the even word-line 8b of the first row through the second word-line hole 4, the fourth word-line hole 4, the sixth word-line hole 4 . . . , respectively. That is, the odd word-line 8a of the word-line of the same row is connected to multiple memory cells (the first part of the memory cells) in the multiple memory subarray layers 1a corresponding to the odd word-line holes 4 of this row; the even word-line 8b of the word-line of the same row are connected to multiple memory cells (the second part of the memory cells) in the multiple memory subarray layers 1a corresponding to the even word-line holes 4 of this row.

As above, each drain region semiconductor strip 11, channel semiconductor strip 12, and source region semiconductor strip 13 has odd word-line holes 4 distributed on one side thereof and even word-line holes 4 distributed on the other side thereof. Therefore, a part of the drain region semiconductor strip 11, channel semiconductor strip 12, and source region semiconductor strip 13 in each same column in each memory subarray layer 1a may cooperate with an odd number gate strip 2 in an odd word-line hole 4 on one side thereof and a storage structure 5 arranged between the gate strip 2 and the drain region semiconductor strip 11, channel semiconductor strip 12, and source region semiconductor strip 13, to form a memory cell, i.e., a first memory cell; and may cooperated with an even word-line hole 4 on the other side thereof and a storage structure 5 arranged therebetween, to form another memory cell, i.e., a second memory cell.

In other words, the gate strip 2 filled in each word-line hole 4 may be configured to form a memory cell (bit) in conjunction with the drain region semiconductor strip 11, the channel semiconductor strip 12, the source region semiconductor strip 13, and the storage structure 5 on the left side in each memory subarray layer 1a; and may be configured to form another memory cell (bit), i.e., a second memory cell, in conjunction with the drain region semiconductor strip 11, the channel semiconductor strip 12, the source region semiconductor strip 13, and the storage structure 5 on the right side in each memory subarray layer 1a.

Therefore, for an odd word-line hole 4, the left half or right half of each drain region semiconductor strip 11, channel semiconductor strip 12, and source region semiconductor strip 13 in the same column in each memory subarray layer 1a may cooperate with the corresponding gate strip 2 in the odd word-line hole 4 to form a first memory cell. Specifically, in each memory subarray layer 1a, for each column of drain region semiconductor strip 11, channel semiconductor strip 12, and source region semiconductor strip 13; for example, word-line holes 4 on the left side of the first column of drain region semiconductor strip 11, channel semiconductor strip 12, and source region semiconductor strip 13 counting from left to right are odd word-line holes, and a part of the drain region semiconductor strip 11, channel semiconductor strip 12, and source region semiconductor strip 13 of that column cooperate with a gate strip 2 in a corresponding odd word-line hole 4 on its left side for forming a first memory cell. Word-line holes 4 on the right side of the second column of the drain region semiconductor strip 11, channel semiconductor strip 12, and source region semiconductor strip 13 counting from left to right are odd word-line holes, and a part of the drain region semiconductor strip 11, channel semiconductor strip 12, and source region semiconductor strip 13 of this column cooperate with a gate strip 2 in a corresponding odd word-line hole 4 on its right side also for constituting a first memory cell.

Similarly, for an even word-line hole 4, the other half of each drain region semiconductor strip 11, channel semiconductor strip 12, and source region semiconductor strip 13 in the same column in each memory subarray layer 1a may cooperate with a corresponding gate strip 2 in the even word-line hole 4 to form a second memory cell. Specifically, in each memory subarray layer 1a, for each column of drain region semiconductor strip 11, channel semiconductor strip 12, and source region semiconductor strip 13: for example, word-line holes 4 on the right side of the first column of drain region semiconductor strip 11, channel semiconductor strip 12, and source region semiconductor strip 13 from left to right are even word-line holes, and a part of the drain region semiconductor strip 11, channel semiconductor strip 12, and source region semiconductor strip 13 of that column cooperate with a gate strip 2 in a corresponding even word-line hole 4 on its right side for forming a second memory cell. Word-line holes 4 on the left side of the second column of the drain region semiconductor strip 11, channel semiconductor strip 12, and source region semiconductor strip 13 from left to right are even word-line holes, and a part of the drain region semiconductor strip 11, channel semiconductor strip 12, and source region semiconductor strip 13 of this column cooperate with a gate strip 2 in a corresponding even word-line hole 4 on its left side also for forming a second memory cell.

Therefore, in the present disclosure, each gate strip 2 in the memory array 1 is connected to a corresponding word-line, and the gate strips 2 in the same row are connected to the corresponding row of word-line. The gate strips 2 in the odd word-line holes 4 in the same row are connected to the odd word-lines 8a in the corresponding row of word-line, and the gate strips 2 in the even word-line holes 4 in the same row are connected to the even word-line 8b in the corresponding row of word-line. In other words, all the first memory cells of the same row in the multiple memory subarray layers 1a are each connected to an odd word-line 8a of the corresponding row through odd number gate strips 2 in odd word-line holes 4 of the same row, and all the second memory cells of the same row in the multiple memory subarray layers 1a are each connected to an even word-line 8a of the corresponding row through even number gate strips 2 in even word-line holes 4 of the same row.

Of course, in other embodiments, it may be, in the same row, every adjacent three, four or five word-line holes 4, etc. are configured as a group, then each line word-line includes three, four, five, etc. different types of word-lines, and the gate strip 2 in each word-line hole 4 in each group is connected to a different type of word-line.

Furthermore, as shown in FIG. 11, in the present disclosure, the number of rows of word-lines may be defined to be the same as the number of rows of word-line holes 4. That is, as shown in FIG. 11, although the gate strips 2 in the word-line holes 4 of the same row are connected to a corresponding odd word-line 8a and a corresponding even word-line 8b, one odd word-line 8a and one even word-line 8b corresponding to the word-line holes 4 of the same row may be defined as one row of word-lines corresponding to the row of gate strips 2 (word-line holes 4). That is, each row of word-line includes one odd word-line 8a and one even word-line 8b, and the number of rows of word-lines is the same as the number of rows of the word-line holes 4. It should also be noted that, as shown in FIG. 11, in each row, each of the left side and right side of a word-line hole 4 not disposed on ends of the memory array correspond to a column of drain region semiconductor strips 11, channel semiconductor strips 12, and source region semiconductor strips 13. However, from left to right, for a word-line hole 4 disposed on a left terminal of the memory array (first terminal), only the right side of the word-line hole 4 corresponds to a column of drain region semiconductor strips 11, channel semiconductor strips 12, and source region semiconductor strips 13; for a word-line hole 4 disposed on a right terminal of the memory array (last terminal), only the left side of the word-line hole 4 corresponds to a column of drain region semiconductor strips 11, channel semiconductor strips 12, and source region semiconductor strips 13. Therefore, it is understood by those skilled in the art that in each row, the word-line hole 4 at the first terminal and the word-line hole 4 at the last terminal functionally constitute a complete word-line hole.

As shown in FIG. 11, in the embodiments, multiple word-lines may be arranged above the multiple memory subarray layers 1a in the memory block 10, each of which is connected to corresponding word-line holes 4 through word-line connection lines 7.

Of course, it is understood by those skilled in the art that multiple word-lines may be arranged on another stacked chip, and the stacked chip may be stacked with and electrically connected to a chip in which the memory block 10 is located. For example, the stacked chip may be stacked with the chip in which the memory block 10 is located by means of hybrid bonding. A terminal of each word-line connection line 7 in the memory block 10 away from the corresponding gate strip 2 serves as a word-line connection terminal of the memory block 10 for connecting to the stacked chip stacked together in the height direction Z of the memory block 10.

In addition, as shown in FIG. 11, in another embodiments, the memory block 10 may further include multiple word-line lead lines 6a or 6b, each word-line further corresponding to a word-line lead line 6a or 6b, respectively, with the word-line lead line 6a or 6b extending in the height direction Z and away from the gate strips 2 with respect to the word-line connection lines 7. A terminal of the word-line lead line 6a or 6b away from the word-line is configured as a word-line connection terminal for connecting to the stacked chip stacked together in the height direction Z of the memory block 10. That is, the word-lines are arranged on the memory array chip and the control circuit is arranged on the other chip. Of course, those skilled in the art can understand that each word-line may be connected to the control circuit on the chip on which the memory block 10 is located through a corresponding word-line lead line 6a or 6b, i.e., the relevant lines, memory array, and control circuit are arranged on the same chip.

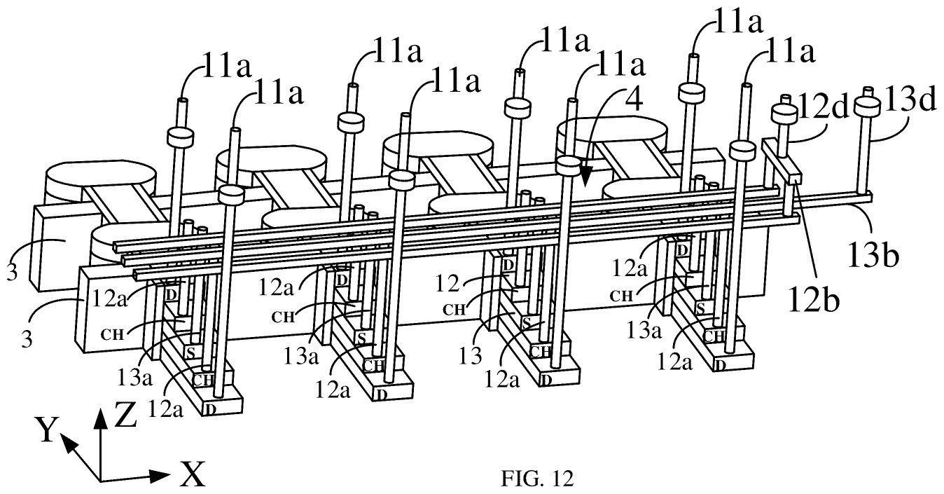

Referring further to FIG. 12, FIG. 12 is a structural schematic view of a circuit connection of part of memory cells of a memory block according to an embodiment of the present disclosure. As shown in FIG. 12, for each column of drain region semiconductor strips 11, channel semiconductor strips 12, and source region semiconductor strips 13 of the multiple memory subarray layers 1a: the multiple drain region semiconductor strips 11 in the same column are led out through different bit line connection lines 11a arranged on an end of each drain region semiconductor strip 11, the bit line connection lines 11a extending along the height direction Z as shown in FIG. 12. For example, for the drain region semiconductor strips 11, the channel semiconductor strips 12, and the source region semiconductor strips 13 in the first column, the drain region semiconductor strip 11 in the first memory subarray layer 1a is led out at its terminal by a bit line connection line 11a, where a terminal of the bit line connection line 11a away from the drain region semiconductor strip 11 may be configured as a bit line connection terminal; the drain region semiconductor strip 11 in the second memory subarray layer 1a is led out at its terminal by another bit line connection line 11a, and a terminal of the another bit line connection line 11a away from the corresponding drain region semiconductor strip 11 is configured as another bit line connection terminal; . . . , and so on. Therefore, each drain region semiconductor strip 11 may serve as a bit line and receive a bit line voltage through the each bit line connection terminal.

It will be understood by those skilled in the art that the memory block 10 may be connected to another stacked chip stacked together in the height direction Z of the memory block 10 through the bit line connection terminal, and provide a bit line voltage to each drain region semiconductor strip 11 in the memory block 10 as a bit line through the bit line connection terminal by means of another stacked chip. Of course, the bit line connection terminal may be further configured to be connected to the control circuit on the chip where the memory block 10 is located, i.e., the relevant lines, the memory array 1, and the control circuit are arranged on the same chip.

Similarly, for each column of drain region semiconductor strips 11, channel semiconductor strips 12, and source region semiconductor strips 13 of the multiple memory subarray layers 1a, the multiple source region semiconductor strips 13 in the same column are led out through different source connection lines 13a disposed on a terminal of each source region semiconductor strip, and the source connection lines 13a extend along the height direction Z.

As shown in FIG. 12, all of the source connection lines 13a in the memory block 10 may be connected to the same common source line 13b, respectively, and a source voltage is applied to the source region semiconductor strips 13 in the memory block 10 through the common source line 13b and the source connection lines 13a.

Of course, it is understood by those skilled in the art that in other embodiments, the memory block 10 may include multiple common source lines 13b, such as a predetermined number of the multiple common source lines 13b, and the source region semiconductor strips 13 in the multiple memory subarray layers 1a may be connected to different multiple common source lines 13b via corresponding source connection lines 13a according to a predetermined rule. In addition, also similar to the bit line connection line 11a corresponding to the drain semiconductor strip 11, a terminal of the source connection line 13a corresponding to each source semiconductor strip 13 away from the source semiconductor strip 13 may be configured as a source connection terminal to receive the source voltage.

Referring further to FIG. 12, the memory block 10 may further include a common source lead line 13d connected to the common source line 13b, where the common source line 13b is connected to all source connection lines 13a in the memory block 10. The common source lead line 13d extends away from the memory array 1 in the memory block 10 and in the height direction Z. A terminal of the common source lead line 13d away from the common source line 13b may be configured as a common source connection terminal for connecting to another stacked chip stacked together in the height direction Z in the memory block 10. Of course, the common source connection terminal may further be configured to connect to the control circuit on the chip on which the memory block 10 is located, i.e., the relevant lines, the memory array, and the control circuit are arranged on the same chip.

Of course, it can be understood by those skilled in the art that the common source line 13b may be arranged in another stacked chip stacked with the memory block 10 in the height direction Z. That is, a terminal of the source connection line 13a away from the corresponding source region semiconductor strip 13 may be configured as a source connection terminal for connection with another stacked chip stacked with the memory block 10 in the height direction Z, such that the common source line 13b are arranged in another stacked chip.

As above, for each column of drain region semiconductor strips 11, channel semiconductor strips 12, and source region semiconductor strips 13 of the multiple memory subarray layers 1a, the multiple channel region semiconductor strips 12 in the same column are led out through different well region connection lines 12a disposed on a terminal of each channel semiconductor strip 12, and the well region connection lines 12a extends along the height direction Z.

As shown in FIG. 12, all of the well region connection lines 12a in the memory block 10 are each connected to the same common well region line 12b, thereby uniformly applying a well region voltage to all the channel semiconductor strips 12 in the memory block 10 through the common well region line 12b.

Of course, it will be understood by those skilled in the art that the corresponding well region connection line 12a of each channel semiconductor strip 12 in the memory block 10 may be connected to multiple separate common well region lines 12b to apply a well voltage to each channel semiconductor strip 12 separately. For example, similar to the above, a terminal of the well region connection line 12a corresponding to each channel semiconductor strip 12 away from the channel semiconductor strip 12 serves as a well connection terminal which is configured to receive a separate well voltage.

Referring further to FIG. 12, all of the well region connection lines 12a in the memory block 10 are each connected to the same common well region line 12b; the memory block 10 may further include a common well region lead line 12d connected to the common well region line 12b, with the common well region lead line 12d extending away from the memory array 1 in the memory block 10 and along the height direction Z. A terminal of the common well region lead line 12d away from the common well region line 12b may be configured as a common well region connection terminal for connection to another stacked chip stacked with the memory block 10 in the height direction Z. Of course, the common well region connection terminal may further be configured for connection to the control circuit on the chip on which the memory block 10 is located, i.e., the associated lines, the memory array 1, and the control circuit are arranged on the same chip. That is, through the common well region line 12b it is possible to connect all the channel semiconductor strips 12 in the memory block 10 together to receive the same well voltage. In the embodiments, the channel semiconductor strip 12 may be a p-type semiconductor strip forming a p-well, and all the channel semiconductor strips 12 in the memory block 10 are connected together through the common well region line 12b, receiving the same well voltage through the common well region line 12b. In addition, in the embodiments, the memory block 10 may read signals through the same common source line 13b.

Of course, it will be understood by those skilled in the art that the common well region line 12b may be arranged in another stacked chip stacked together with the memory block 10 in the height direction Z. That is, a terminal of the well region connection line 12a away from the corresponding channel semiconductor strip 12 may be configured as a well region connection terminal for connection to another stacked chip stacked together with the memory block 10 in the height direction Z, thereby arranging the common well region line 12b in another stacked chip.

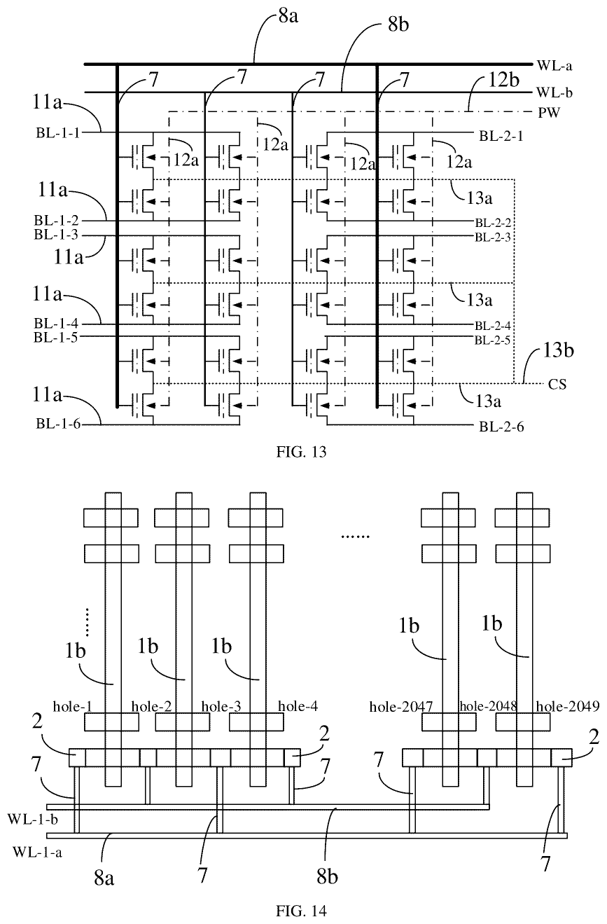

In some embodiments, it is noted that, as shown in FIG. 11 and FIG. 13, in the present disclosure, connecting wires, such as word-line 8a or 8b, word-line connection line 7, word-line lead line 6a or 6b, common source line 13b, common well region line 12b, etc. are arranged in the memory block 10, especially on the same side of the memory array 1 in the memory block 10, i.e., arranged above the memory array 1. Therefore, it may be ensured that the drain region semiconductor strips 11, the channel semiconductor strips 12, and the source region semiconductor strips 13 in the memory array 1may be each formed as single-crystal semiconductor strips by epitaxial growth, while only polycrystalline semiconductor strips can be formed by the deposition method. Compared to polycrystalline semiconductor strips formed by deposition, the drain region semiconductor strips 11, channel semiconductor strips 12, and source region semiconductor strips 13 formed by epitaxial growth of the present disclosure may have superior device performance and greatly improve the performance of the relevant memory device. Specifically, when comparing the memory cell adopted with a single-crystal semiconductor (single-crystal drain region semiconductor strip 11, channel semiconductor strip 12, and source region semiconductor strip 13) to the memory cell adopted with a polycrystalline semiconductor, the memory cell with the polycrystalline semiconductor has more interfaces, along which electrons move when passing through the polycrystalline semiconductor, i.e., the distance of electron movement increases and the current decreases significantly. According to a practical empirical test, the current of the memory cell with a polycrystalline semiconductor is only 1/10 of the current of the memory cell with a single-crystal semiconductor. Therefore, the memory block 10 of the present disclosure, with the memory cell with a single-crystal semiconductor, may greatly improve the performance of the memory device. In addition, the low current of the memory cell with the polycrystalline semiconductor affects the read window between the read/write operation (PGM) and the erase operation (ERS) of the memory cell, which has a great impact on the reliability of the memory device, especially for the NOR memory device. In addition, for NOR memory devices, when a hot carrier injection (HCl) method is applied for read/write operations, a single-crystal semiconductor must be adopted to accomplish this.

In addition, since the connecting wires in the present disclosure are arranged on the same side of the memory array 1 in the memory block 10, it is more convenient to perform the bonding stacking process in three dimensions with the stacked chips, thereby improving the performance of the related memory devices, and manufacturing the chips separately is conducive to optimizing the process and reducing the manufacturing time.

It can be understood by those skilled in the art that in some embodiments, in order for the memory block 10 to obtain better performance, the outermost memory cell may generally serve as a dummy memory cell (dummy cell) and does not perform actual storage works. For example, the memory cells included in the lowermost memory subarray layer 1a may be configured as dummy memory cells. In addition, in some embodiments, the leftmost and rightmost columns of the memory block 10 are each arranged with a column of drain region semiconductor strips 11, channel semiconductor strips 12, and source region semiconductor strips 13, respectively. The memory cells formed by the leftmost column of the drain region semiconductor strips 11, the channel semiconductor strips 12, and the source region semiconductor strips 13, together with the gate strips 2 in the word-line holes 4 on the right side and the storage structures 5 between them, and the memory cells formed by the rightmost column of drain region semiconductor strips 11, channel semiconductor strips 12 and source region semiconductor strips 13, together with the gate strips 2 in the word-line hole 4 on the left side and the storage structures 5 between them, are also taken as dummy memory cells not participating in the actual storage work.

Therefore, in the present disclosure, unless intentionally pointed out, the memory subarray layers 1a in the entire specification do not include the lowermost memory subarray layer involved in the dummy memory cells (dummy cells); nor do the drain region semiconductor strips 11, the channel semiconductor strips 12, and the source region semiconductor strips 13 include the leftmost column of drain region semiconductor strips 11, channel semiconductor strips 12, and source region semiconductor strips 13, and the rightmost column of drain region semiconductor strips 11, channel semiconductor strips 12, and source region semiconductor strips 13, involved in the dummy memory cells (dummy cells).

Therefore, as above, in the same row, from left to right, the first word-line hole 4 only corresponds to a column of drain region semiconductor strips 11, channel semiconductor strips 12, and source region semiconductor strips 13 on the right side; the last word-line hole 4 only corresponds to a column of drain region semiconductor strips 11, channel semiconductor strips 12, and source region semiconductor strips 13 on the left side. Therefore, those skilled in the art can understand that the first and last word-line holes functionally constitute a complete word-line hole.

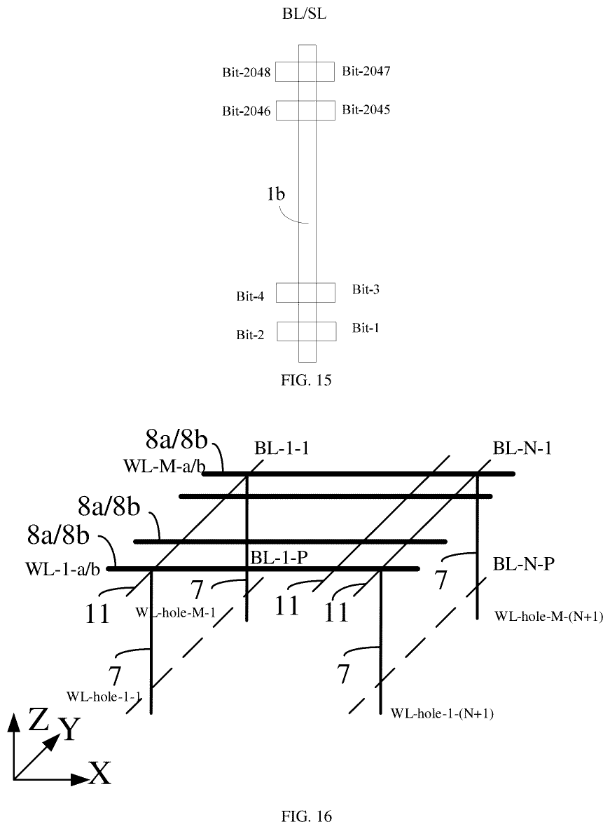

In conjunction with FIG. 13 to FIG. 16, FIG. 13 is a schematic view of a circuitry of the memory block 10 shown in FIG. 11, FIG. 14 is a schematic sketch of a plan view of the memory block 10 shown in FIG. 11, FIG. 15 is a schematic view of a memory cell corresponding to each layer of bit lines, and FIG. 16 is a schematic view of a three-dimensional distribution of word-lines and bit lines.

As shown in FIG. 13, the memory block 10 includes multiple memory subarray layers 1a (six layers herein illustrated in FIG. 13), and the drain region semiconductor strips 11 in the multiple memory subarray layers 1a serve as bit lines, such as BL-1-1, BL-1-2, BL-1-3, BL-1-4, BL-1-5, BL-1-6; multiple columns of drain region semiconductor strips 11 in each memory subarray layer 1a constitute multiple columns of bit lines, such as BL-1-1, BL-2-1, . . . ; the source region semiconductors 13 in the multiple memory subarray layers 1a in memory block 10 are connected to a common source line 13b; the well region semiconductors 12 in the multiple memory subarray layers 1a in memory block 10 are connected to a common well region line 12b. In addition, the gate strip 2 in the same word-line hole 4, together with the drain region semiconductor layers 11, the channel region semiconductor layers 12, and the source region semiconductor layers 13 on the left and right sides, forms two columns of memory cells (as shown in the middle two columns of memory cells), respectively. The gate strips 2 corresponding to the odd number word holes 4 are connected to an odd word-line WL-a, such as the first, fourth column memory cells, which correspond to the first word-line holes and third word-line holes, respectively; and the gate strips 2 corresponding to the even number word holes 4 are connected to an even word-line WL-b, such as the second, third column memory cells, which correspond to the second word-line holes.

As shown in FIG. 14 to FIG. 16, in each memory subarray layer 1a, for the drain region semiconductor strips 11, channel semiconductor strips 12, and source region semiconductor strips 13 extending along the column direction, one column of semiconductor strip structure 1b forms a memory cell (bit) with the gate strip 2 in the left word-line hole 4 and another memory cell (bit) with the gate strip 2 in the right word-line hole 4. The first row of odd word-line holes 4, such as hole-1, hole-3, . . . , are connected to the first row of odd word-line WL-1-a, and the first row of even word-line holes, such as hole-2, hole-4, . . . , are connected to the first row of even word-line WL-1-b.

As shown in FIG. 16, assume that the memory block 10 includes P layers of memory subarray layers 1a, M rows of word-lines, and N columns of bit lines. Then, each memory subarray layer 1a includes N columns of drain region semiconductor strips 11 as bit lines, such as shown as BL-1-1, . . . , BL-N-1; for the P-th memory subarray layer 1a, such as BL-1-1, . . . , BL-N-P as shown, the memory block 10 includes N*P drain region semiconductor strips 11 as bit lines. M rows of word-lines, e.g., WL-1-a/b, . . . , WL-M-a/b, each have a projection crossed with a projection of each of the N columns of bit lines on a projection plane defined by the row direction X and column direction Y, respectively, to form multiple memory cells. P, M and N are all natural numbers greater than 0.

According to the above conditions, it is understood by those skilled in the art that in the same row direction X, the memory block 10 includes (N+1) word-line holes 4, such as shown as WL-hole-1-1, . . . , WL-hole-1-(N+1); and in the same column direction Y, the memory block 10 includes M word-line holes 4, such as shown as WL-hole-1-(N+1), . . . , WL-hole-M-(N+1). A side of each column of drain region semiconductor strips 11, channel semiconductor strips 12, and source region semiconductor strips 13 corresponds to M word-line holes 4. Each row of word-lines (one odd word-line 8a and one even word-line 8b) corresponds to (N+1) word-line holes 4. As above, in the same row, the word-line holes 4 at the first and last ends each correspond to only one memory cell in each memory subarray layer 1a, and therefore the word-line holes 4 at the first and last ends can be functionally regarded as a complete word-line hole; while other word-line holes 4 correspond to two memory cells (one on each of the left and right sides) in each memory subarray layer 1a. Therefore, each row of word-lines corresponds to N*2*P memory cells. When N is an even number, an odd word-line 8a corresponds to (N/2+1) word-line holes, which includes word-line holes 4 at the first and last ends of the same row, that is, an odd word-line 8a also corresponds to N/2 complete word-line holes 4, corresponding to (N/2)*P*2 memory cells. An even word-line 8b corresponds to N/2 word-line holes 4, corresponding to (N/2)*P*2 memory cells. In other words, the number of memory cells corresponding to an odd word-lines 8a and the number of memory cells corresponding to an even word-lines 8b are the same.

In some embodiments, assume that the memory block 10 specifically includes 8 layers of the memory subarray layers 1a and 1024 rows of word-lines, each row of word-lines includes an odd word-line 8a and an even word-line 8b, each layer of the memory subarray layer 1a includes 2048 columns of the drain region semiconductor strips 11 as bit lines, and the memory block 10 includes 2048*8 of the drain region semiconductor strips 11 as bit lines.

In the same row direction X, the memory block 10 includes (2048+1=2049) word-line holes 4; in the same column direction Y, the memory block 10 includes 1024 word-line holes 4. Each drain region semiconductor strip 11 as a bit line corresponds to 1024 word-line holes 4, corresponding to 1024*2 memory cells. Each row of word-lines corresponds to (2048+1=2049) word-line holes 4. The word-line holes 4 at the first and last terminals each correspond to only one memory cell in each memory subarray layer 1a, which functionally constitutes a complete word-line hole 4, which corresponds to 2048*2*8=32K memory cells. N is an even number 2048, then an odd word-line 8a corresponds to (2048/2+1=1025) word-line holes, which includes the word-line holes 4 at the first and last ends of the same row, that is, an odd word-line 8a also corresponds to 1024 complete word-line holes 4, which corresponds to (2048/2)*8*2 memory cells; an even word-line 8b corresponds to 2048/2 word-line holes 4, which corresponds to (2048/2)*8*2 memory cells.

In the memory block 10, ⅛ of the memory cells corresponding to a word-line, that is, 1024*2 memory cells, may be defined as one memory page (128 complete word-line holes 4). In the memory block 10, 32K memory cells corresponding to one word-line may be defined as a sector, which can be understood that one sector corresponds to 2 word-lines, (2048+1) word-line holes 4 (2048 complete word-line holes 4), and 2048*2*8 memory cells (bit).

In the memory block 10, 16 sectors may be defined to form a sub memory block 10 (eblk) including 0.5M memory cells (2048*2*8*16=1024*2*2*8*16=1024*1024*0.5). In specific embodiments, the memory block 10 includes 64 sub memory blocks 10 including 32M memory cells. Each memory block 10 shares a common source line 13b and a common well region line 12b.

The memory block 10 provided in the embodiments includes a memory array 1, and the memory array 1 includes multiple memory cells distributed in a three-dimensional array; the memory array 1 includes multiple memory subarray layers 1a stacked sequentially along a height direction Z, and each memory subarray layer 1a includes a drain region semiconductor layer, a channel semiconductor layer, and a source region semiconductor layer stacked along the height direction Z; the drain region semiconductor layer, channel semiconductor layer, and source region semiconductor layer in each memory subarray layer 1a include multiple drain region semiconductor strips 11, channel semiconductor strips 12, and source region semiconductor strips 13, respectively, distributed along a row direction X, and each drain region semiconductor strip 11, channel semiconductor strip 12, and source region semiconductor strip 13 extends along a column direction Y; multiple gate strips 2 distributed along the column direction Y are arranged on each side of each column of drain region semiconductor strips 11, channel semiconductor strips 12, and source region semiconductor strips 13, each gate strip 2 extending along the height direction Z; in the height direction Z, a projection of at least a part of each gate strip 2 coincides with a projection of a part of a corresponding channel semiconductor strip 12 in each memory subarray layer 1a on a projection plane, the projection plane extending along the height direction Z and the column direction Y. A part of the gate strip 2, a corresponding part of the channel semiconductor strip 12, a part of the drain region semiconductor strip 11 adjacent to the corresponding part of the channel semiconductor strip 12, and a part of the source region semiconductor strip 13 adjacent to the corresponding part of the channel semiconductor strip 12 are configured to form a memory cell. The memory block 10 has a higher storage density compared to a two-dimensional memory array.

As above, the memory block 10 of the present disclosure includes at least two structures of memory cells. In some embodiments, in combination with FIG. 5, FIG. 7, FIG. 8 and FIG. 10, a memory cell is provided that includes a drain region portion 11′, a channel portion 12′, a source region portion 13′, and a gate portion 2′. The drain region portion 11′, the channel portion 12′, and the source region portion 13′ are stacked along the height direction Z, and the gate portion 2′ is disposed on one side of the drain region portion 11′, the channel portion 12′, and the source region portion 13′, and extends along the height direction Z. In the height direction Z, a projection of the gate portion 2′ partially overlaps with a projection of the channel portion 12′ on a projection plane extending along the height direction Z. A storage structure portion 5′ is arranged between the gate portion 2′ and the drain region portion 11′, the channel portion 12′, and the source region portion 13′.

The drain region portion 11′ is a part of the drain region semiconductor layer, the channel portion 12′ is a part of the channel semiconductor layer, and the source region portion 13′ is a part of the source region semiconductor layer of the memory block 10 provided in the above embodiments. The specific structures, functions, and lamination methods of the drain region portion 11′, the channel portion 12′, the source region portion 13′, and the storage structure portion 5′ can be found in those of the drain region semiconductor layer, the channel semiconductor layer, the source region semiconductor layer, and the storage structure 5′ in each of the memory subarray layers 1a described above, and the same or similar technical effects can be achieved, which will not be repeated herein.

When the drain region portion 11′, the channel portion 12′, and the source region portion 13′ are each in a strip structure and the storage structure portion 5′ is a charge trapping storage structure portion, the specific structure of the memory cell can be seen in FIG. 5, and other structures of the memory cell can be seen in the relevant description of FIG. 5 above. When the drain region portion 11′, the channel portion 12′, and the source region portion 13′ each include the body structure 15a and multiple protrusions 15b, and the storage structure portion 5′ is a charge trapping storage structure portion, the specific structure of the memory cell can be seen in FIG. 7, and other structures of the memory cell can be found in the above description of FIG. 7. When the storage structure portion 5′ is a floating gate storage structure portion, the specific structure of the memory cell can be seen in FIG. 10 and FIG. 11, and other structures of the memory cell can be seen in the above description of FIG. 10 and FIG. 11.

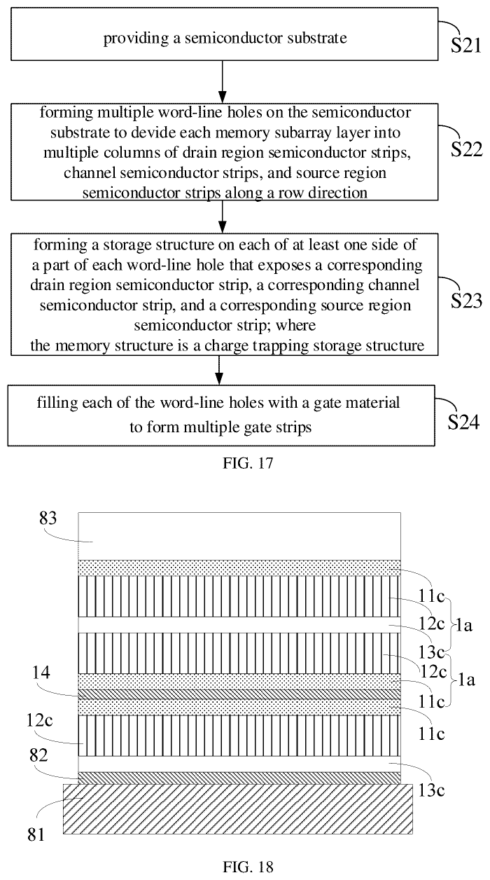

As shown in FIG. 17, FIG. 17 is a flowchart of a manufacturing method of a memory block according to an embodiment of the present disclosure. In the embodiments, a manufacturing method of a memory block is provided that may be configured to prepare the memory block 10 provided in FIG. 2a to FIG. 4 of the above embodiments, to obtain the memory block 10 with relatively high storage density. The storage structure 5 of the memory block 10 is a charge trapping storage structure. Specifically, the method includes operations at blocks illustrated in FIG. 17.
At step S21: providing a semiconductor substrate.

As shown in FIG. 18, FIG. 18 is a cross-sectional view of a semiconductor substrate according to an embodiment of the present disclosure. The semiconductor substrate includes a substrate 81, a first single-crystal sacrificial semiconductor layer 82 arranged on the substrate 81, and two memory subarray layers 1a and a second single-crystal sacrificial semiconductor layer 14 stacked and formed alternately in sequence on the first single-crystal sacrificial semiconductor layer 82, until another two memory subarray layers 1a are formed uppermost.

The substrate 81 may be a single-crystal substrate 81; specifically, it may be made of single-crystal silicon. The first single-crystal sacrificial semiconductor layer 82 and/or the second single-crystal sacrificial semiconductor layer 14 may be made of silicon germanium (SiGe). The multiple memory subarray layers 1a are sequentially layered in a height direction Z perpendicular to the substrate 81. Each memory subarray layer 1a includes a drain region semiconductor layer 11c, a channel semiconductor layer 12c′, and a source region semiconductor layer 13c stacked along the height direction Z. Two adjacent memory subarray layers 1a in the height direction Z may share a common source region. The two adjacent memory subarray layers 1a may include sequentially stacked drain region semiconductor layer 11c, channel semiconductor layer 12c′, source region semiconductor layer 13c, channel semiconductor layer 12c′, and drain region semiconductor layer 11c, to achieve sharing the common source region semiconductor layer 13c. Therefore, for common source memory subarray layers 1a, a second single-crystal sacrificial semiconductor layer 14 is arranged on every two memory subarray layers 1a to isolate from the other two memory subarray layers 1a. The second single-crystal sacrificial semiconductor layer 14 may be made of silicon germanium (SiGe).

It should be noted that the structure shown in FIG. 18 only exemplarily illustrates part of the structure of the semiconductor substrate; it is understood by those skilled in the art that between the first single-crystal sacrificial semiconductor layer 82 and the second single-crystal sacrificial semiconductor layer 14 shown in FIG. 18, two memory subarray layers 1a sharing a common source region semiconductor layer 13c are arranged. For the sake of brevity of the accompanying drawings, one layer of the memory subarray layer 1a is shown schematically only for illustrative purposes only.

In some embodiments, step S21 may specifically include the following.
Step S211a: providing a substrate 81.

The substrate 81 may be a single-crystal substrate 81; specifically, it may be single-crystal silicon.

Step S212a: forming multiple memory subarray layers 1a sequentially on the substrate 81 along the height direction Z.
Step S212a may specifically include the following.
Step a: forming the first single-crystal sacrificial semiconductor layer 82 on the substrate 81 by epitaxial growth.

The first single-crystal sacrificial semiconductor layer 82 may be silicon germanium (SiGe).
Step b: forming two memory subarray layers 1a and a second single-crystal sacrificial semiconductor layer 14 alternately in sequence by epitaxial growth on the first single-crystal sacrificial semiconductor layer 82; continuing to form another two memory subarray layers 1a, optionally continuing to repeatedly stack another second single-crystal sacrificial semiconductor layer 14 and another two common source memory subarray layers 1a, until forming uppermost two common source memory subarray layers.

The material of the second single-crystal sacrificial semiconductor layer 14 is the same as the material of the first single-crystal sacrificial semiconductor layer 82, which may also be silicon germanium (SiGe).

It is understood by those skilled in the art that the purpose of providing the first single-crystal sacrificial semiconductor layer 82 on the substrate 81 first is to avoid electrical leakage caused by the multiple memory subarray layers 1a directly contacting the substrate 81. However, as above, the device performance of the lowermost memory subarray layer 1a in the memory block of the present disclosure is poor, and therefore, the memory cells in the lowermost memory subarray layer 1a are generally configured as dummy memory cells and do not participate in the actual memory work. Therefore, it is understood by those skilled in the art that the first single-crystal sacrificial semiconductor layer 82 may not be arranged on the substrate 81, and a single memory subarray layer 1a or two common source memory subarray layers 1a are formed directly on the substrate 81 as dummy memory cells, on which the second single-crystal sacrificial semiconductor layer 14 and two common source memory subarray layers 1a are alternately formed by epitaxial growth until the uppermost layer of two common source memory subarray layers 1a are formed. That is, the lowermost one memory subarray layer 1a or two common source memory subarray layers 1a, as a dummy memory cell(s), does not participate in the actual memory work, and therefore, it can also prevent electrical leakage to the substrate 81.

Two adjacent memory subarray layers 1a share a common source region, and a manufacturing method of each two adjacent memory subarray layers sharing the common source region may include the following.
Step b1: forming a first single-crystal semiconductor layer of a first doping type by epitaxial growth on the first single-crystal sacrificial semiconductor layer 82 or the second single-crystal sacrificial semiconductor layer 14 of the lower layer.

Specifically, a semiconductor material gas and a first type of dopant ion gas may be simultaneously introduced to form one layer of the first single-crystal semiconductor layer of the first doping type on the first single-crystal sacrificial semiconductor layer 82 or the second single-crystal sacrificial semiconductor layer 14 of the lower layer by epitaxial growth. The first single-crystal semiconductor layer serves as a drain region semiconductor layer 11c (or a source region semiconductor layer 13c). The first type of dopant ion may be an arsenic ion. The semiconductor material may be an existing semiconductor material for forming the drain region (or source region).
Step b2: forming a second single-crystal semiconductor layer of a second doping type on the first single-crystal semiconductor layer by epitaxial growth.

Specifically, a semiconductor material gas and a second type of dopant ion gas may be simultaneously fed to form one layer of the second single-crystal semiconductor layer of the second doping type on the first single-crystal semiconductor layer by epitaxial growth. The second single-crystal semiconductor layer serves as a channel semiconductor layer 12c′. The second type of dopant ion may be a BF2+ ion. The semiconductor material may be an existing semiconductor material for forming a well region.
Step b3: forming a third single-crystal semiconductor layer of the first doping type on the second single-crystal semiconductor layer by epitaxial growth.

Specifically, a semiconductor material gas and a first type of dopant ion gas may be simultaneously fed to form one layer of the third single-crystal semiconductor layer of the first doping type on the second single-crystal semiconductor layer by epitaxial growth. The third single-crystal semiconductor layer serves as a source region semiconductor layer 13c (or a drain region semiconductor layer 11c). The first type of dopant ion may be an arsenic ion. The semiconductor material may be an existing semiconductor material for forming the source drain region (or drain region).

In a specific implementation of step S212a, one layer of the second single-crystal sacrificial semiconductor layer 14 is further formed between every two memory subarray layers 1a. Each two adjacent memory subarray layers 1a separated by the second single-crystal sacrificial semiconductor layer 14 in the height direction Z includes sequentially stacked drain region semiconductor layer 11c, channel semiconductor layer 12c′, source region semiconductor layer 13c, channel semiconductor layer 12c′, and drain region semiconductor layer 11c to share the same source region semiconductor layer 13c.
Step b4: forming a fourth single-crystal semiconductor layer of the second doping type on the third single-crystal semiconductor layer by epitaxial growth.

This step b4 is performed in a similar manner to step b2. The fourth single-crystal semiconductor layer serve as the channel semiconductor layer 12c′.
Step b5: forming a fifth single-crystal semiconductor layer of the first doping type on the fourth single-crystal semiconductor layer by epitaxial growth.

This step b5 is performed in a similar manner as step b1. The fifth single-crystal semiconductor layer serve as the drain region semiconductor layer 11c (or source region semiconductor layer 13c).

The first single-crystal semiconductor layer, the second single-crystal semiconductor layer, and the third single-crystal semiconductor layer form a memory subarray layer 1a; the third single-crystal semiconductor layer, the fourth single-crystal semiconductor layer, and the fifth single-crystal semiconductor layer form another memory subarray layer 1a; and the two memory subarray layers 1a share the third single-crystal semiconductor layer as a shared source region semiconductor layer 13c.

It is understood that, in the embodiments, after step b5, one layer of the second single-crystal sacrificial semiconductor layer 14 is formed on the fifth single-crystal semiconductor layer, after which steps b1-b5 may be repeated on the second single-crystal sacrificial semiconductor layer 14 until a predetermined number of layers of the memory subarray layers 1a is formed.

That is, a second single-crystal sacrificial semiconductor layer 14 is formed between every two memory subarray layers 1a. Moreover, each adjacent two memory subarray layers 1a separated by the second single-crystal sacrificial semiconductor layer 14 in the height direction Z includes sequentially stacked drain region semiconductor layer 11c, channel semiconductor layer 12c′, source region semiconductor layer 13c, channel semiconductor layer 12c′, and drain region semiconductor layer 11c to share the same source region semiconductor layer 13c.
Step S213a: forming a first hard mask layer 83 on the multiple memory subarray layers 1a, and forming multiple isolation wall holes 31 in the first hard mask layer 83 and the multiple memory subarray layers 1a, and filling the multiple isolation wall holes 31 with an isolation material to form multiple isolation walls 3 to form the semiconductor substrate.

The first hard mask layer 83 may be made of silicon dioxide or silicon nitride.

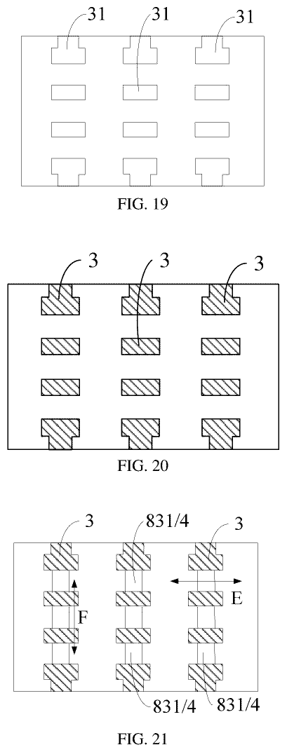

Specifically, referring to FIG. 19, FIG. 19 is a top view of forming multiple isolation wall holes 31 in the memory subarray layers 1a. The multiple isolation wall holes 31 may be formed etching, and the isolation wall holes 31 are arranged in a matrix in the row direction X and the column direction Y, with each isolation wall hole 31 extending along the height direction Z to a surface of the substrate 81. The specific structure of forming the isolation walls 3 in the isolation wall holes 31 can be seen in FIG. 20, which is a top view of the multiple isolation walls 3 formed in the isolation wall holes 31 shown in FIG. 19. Specifically, the isolation wall 3 near an edge of the memory block 10 in the column direction Y extends further in the column direction Y to the edge of the memory block 10 to ensure that the isolation wall 3 at the edge of the column direction Y can completely isolate two adjacent columns stacked structures 1b′. Specifically, in some embodiments, the isolation wall 3 near the edge of the memory block 10 in the column direction Y is a T-shaped isolation wall 3, i.e., the isolation wall 3 includes a lateral portion and a protruding portion toward the edge of the memory block 10 in the column direction Y, and the protruding portion is in contact with the edge of the memory block 10 in the column direction Y to completely isolate the two adjacent column stack structures 1b′ to prevent a short circuit between the two columns of the drain region semiconductor strips 11, the channel semiconductor strips 12, and the source region semiconductor strips 13. The isolation wall 3 and the first hard mask layer 83 may be made of the same material.

In other embodiments, step S21 specifically includes the following operations.
Step S211b: providing the substrate 81.
Step S212b: forming multiple isolation walls 3 on the substrate 81, where the multiple isolation walls 3 are arranged in a matrix in the row direction X and the column direction Y, each isolation wall 3 extending along the height direction Z perpendicular to the substrate 81.
Step S213b: forming multiple memory subarray layers 1a sequentially on the substrate 81 and between the multiple isolation walls 3 along the height direction Z.

The specific implementation process of forming the multiple memory subarray layers 1a is the same or similar to the specific implementation process of forming the multiple memory subarray layers 1a in step S212a above, and the same or similar technical effect can be achieved, as described above.
Step S214b : forming a first hard mask layer 83 on the above structure to form the semiconductor substrate.

Specifically, the first hard mask layer 83 may be formed on the product structure after being processed by step S213b, with the first hard mask layer 83 being disposed on a side surface of the multiple memory subarray layers 1a back from the substrate 81.

At step S22: forming multiple word-line holes on the semiconductor substrate to divide each memory subarray layer into multiple columns of drain region semiconductor strips, channel semiconductor strips, and source region semiconductor strips along a row direction.

In some embodiments, step S22 specifically includes the following.
Step S221: forming the multiple word-line openings 831 on the first hard mask layer 83.

As shown in FIG. 21, FIG. 21 is a top view of forming the multiple word-line openings 831 and word-line holes 4 on the semiconductor substrate. The multiple word-line openings 831 may be formed on the first hard mask layer 83 by etching. The multiple word-line openings 831 are arranged in a matrix in the row direction X and the column direction Y.
Step S222: etching the multiple memory subarray layers 1a under the first hard mask layer 83 to form multiple word-line holes 4.

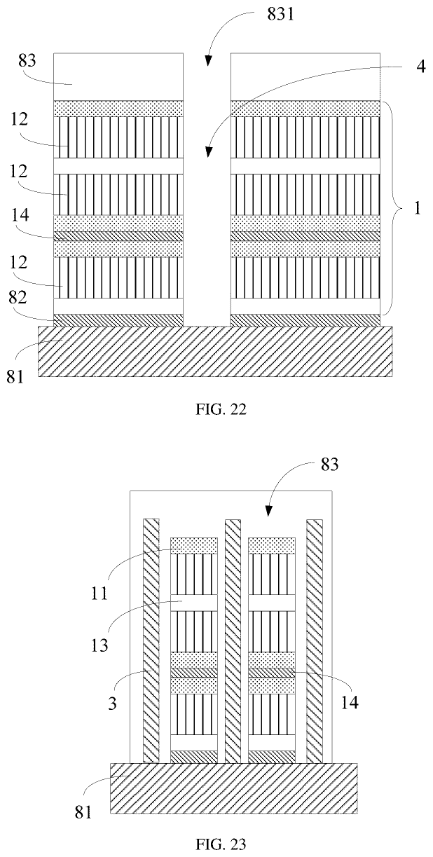

As shown in FIG. 21 to FIG. 23, FIG. 22 is a cross-sectional view in the E-direction of the product corresponding to FIG. 21; and FIG. 23 is a cross-sectional view in the F-direction of the product corresponding to FIG. 21. Specifically, the word-line holes 4 may be formed by etching, and as shown in FIG. 21, the multiple word-line holes 4 are spaced apart from the isolation walls 3; and the multiple word-line holes 4 are arranged in a matrix in the row direction X and column direction Y, and each memory subarray layer 1a is divided into multiple columns of drain region semiconductor strips 11, channel semiconductor strips 12, and source region semiconductor strips 13 along the row direction X. As shown in FIG. 22, each word-line hole 4 extends along the height direction Z, and the left and right sides (such as the left and right sides in the orientation of FIG. 22) of each word-line hole 4 at a non-edge position expose parts of two columns of drain region semiconductor strips 11, channel semiconductor strips 12, and source region semiconductor strips 13 of the multiple memory subarray layers 1a, respectively. Each word-line hole 4′ s both sides in the left-right direction are the drain region semiconductor strips 11, channel semiconductor strips 12 and, source region semiconductor strips 13; both sides in the front-rear direction are isolation walls 3. In this step, an etchant with a high etch ratio for the semiconductor material and a low etch ratio for the isolation wall 3 may be applied to process the formation of the word-line holes 4. In addition, as shown in FIG. 2a to FIG. 4, the leftmost edge word-line holes 4 correspond to only one column of the drain region semiconductor strips 11, channel semiconductor strips 12 and, source region semiconductor strips 13 on right side; similarly, the rightmost edge word-line holes 4 correspond to only one column of the drain region semiconductor strips 11, channel semiconductor strips 12 and, source region semiconductor strips 13 on left side. However, it is understood by those skilled in the art that the leftmost edge line holes 4 and the rightmost edge line holes 4 can be considered as a combination to form a complete word-line hole, and the differences in the edge word-line holes 4 will not be specifically noted subsequently.

As shown in FIG. 2a, FIG. 2b, and FIG. 4, the multiple word-line holes 4 together with the multiple isolation walls 3 divide the drain region semiconductor layer 11c in each memory subarray layer 1a into multiple drain region semiconductor strips 11 spaced at intervals along the row direction X; the channel semiconductor layer 12c into multiple channel semiconductor strips 12 spaced at intervals along the row direction X; and the source region semiconductor layer 13c into multiple source region semiconductor strips 13 spaced at intervals along the row direction X. The other specific structures and functions of each drain region semiconductor strip 11, channel semiconductor strip 12, and source region semiconductor strip 13 can be found in the above description and will not be repeated here. In addition, as shown in FIG. 23, the interior of the isolation wall 3 may be silicon oxide with a layer of silicon nitride wrapped around the outside, and the silicon nitride wrapped around the outside may be the same as the material of the first hard mask layer 83.

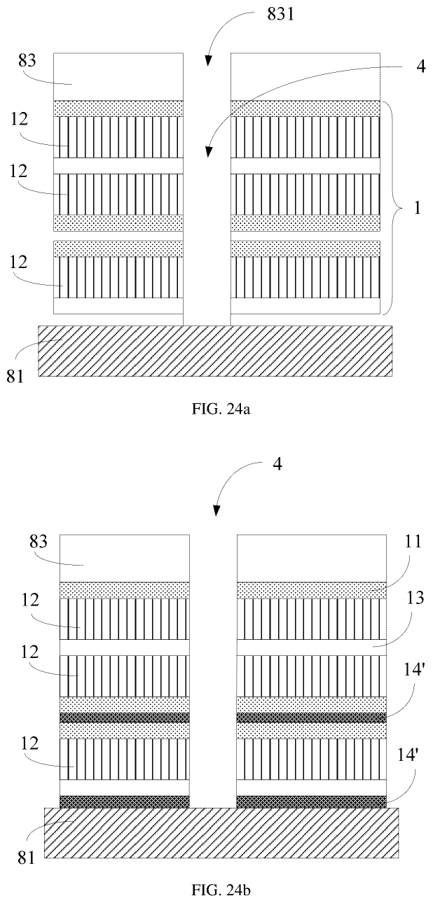

In a specific implementation, referring to FIG. 24a and FIG. 24b, FIG. 24a is a schematic view of the structure shown in FIG. 21 after being processed by step S223; FIG. 24b is a schematic view of the structure shown in FIG. 24a after being filled with the insulating material; after step S222, the method may further include the following.
Step S223: removing the first single-crystal sacrificial semiconductor layer 82 and the second single-crystal sacrificial semiconductor layer 14 through the word-line holes 4.

Specifically, the first single-crystal sacrificial semiconductor layer 82 and the second single-crystal sacrificial semiconductor layer 14 may be removed by etching.
Step S224: depositing on regions where the removed first single-crystal sacrificial semiconductor layer 82 and the second single-crystal sacrificial semiconductor layer 14 were located to fill the regions with an insulating material, thereby replacing the first single-crystal sacrificial semiconductor layer 82 and the second single-crystal sacrificial semiconductor layer 14 with an insulating isolation layer 14′.

The insulating material may be filled by means of atomic layer deposition. The insulating material may specifically be silicon oxide. It will be understood by those skilled in the art that after step S223 removing the first single-crystal sacrificial semiconductor layer 82 and the second single-crystal sacrificial semiconductor layer 14, the isolation walls 3 may provide sufficient support to the adjacent stacked structures 1b′ to facilitate subsequent execution of step S224.

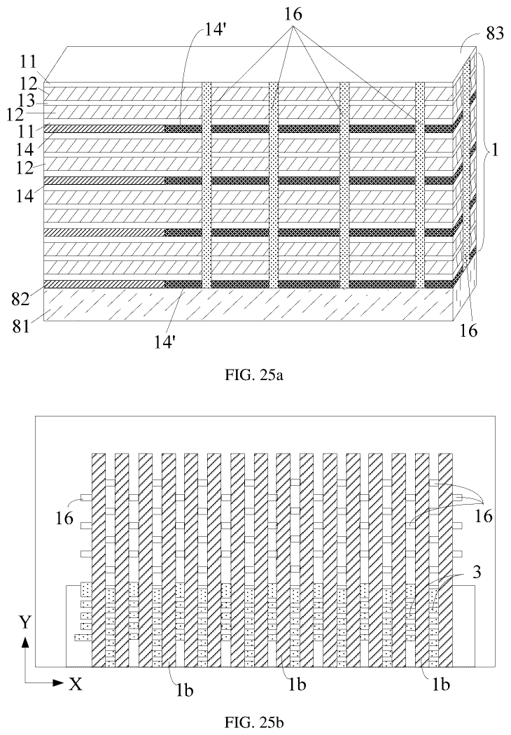

Further, it will be understood by those skilled in the art that in some embodiments, the memory array 1 further includes multiple support posts 16. Specifically, referring to FIG. 25a and FIG. 25b. FIG. 25a is a schematic view of a perspective structure of a memory array according to an embodiment of the present disclosure; and FIG. 25b is a partial plan schematic view of a memory array according to an embodiment of the present disclosure.

As shown in FIG. 25a and FIG. 25b, the memory array 1 further includes multiple support posts 16, each of which extends along the height direction Z of the memory array 1.

As described above, the first single-crystal sacrificial semiconductor layer 82 and the second single-crystal sacrificial semiconductor layer 14 are required to be replaced with the insulating isolation layer 14′. In this step, the first single-crystal sacrificial semiconductor layer 82 and the second single-crystal sacrificial semiconductor layer 14 are partially replaced with the insulating isolation layer 14′, but in subsequent steps, all of the first single-crystal sacrificial semiconductor layer 82 and the second single-crystal sacrificial semiconductor layer 14 are replaced with the insulating isolation layer 14′ as required for electrical isolation. That is, during the manufacturing of the memory array 1, after etching off the first single-crystal sacrificial semiconductor layer 82 and/or the second single-crystal sacrificial semiconductor layer 14, the memory subarray layers 1a in the relevant regions are overhanging. In these relevant regions, when the isolation walls 3 are provided, the isolation walls 3 can provide sufficient support to the overhanging memory subarray layers 1a in these regions to prevent the memory subarray layers 1a from collapsing.

However, the isolation walls 3 may not present in some regions. For example, in a drain/source lead region, the memory subarray layers 1a in this region are not required to manufacture the memory cells, and the drain region semiconductor strips 11, source region semiconductor strips 13, and/or channel semiconductor strips 12 in the memory subarray layers 1a in this region are required to be led out to be connected with corresponding wires. Therefore, in these regions, multiple support posts 16 are required to be arranged between two columns of the stacked structures 1b′. In this way, after etching the first single-crystal sacrificial semiconductor layer 82 and/or the second single-crystal sacrificial semiconductor layer 14 in the stacked structures 1b′ in these regions during the manufacturing of the memory array 1, the support posts 16 can provide sufficient support to the overhanging memory subarray layers 1a to prevent the memory subarray layers 1a from collapsing, and support the frame of the memory array 1 and maintain the structural stability of the memory array 1.

It will be understood by those skilled in the art that the support posts 16 may be made of the same material as the isolation wall 3 and manufactured in the same process steps as the isolation wall 3. That is, the isolation wall 3 and the support post 16 are similar in nature, except that the isolation wall 3 is arranged in the region of the memory array 1 where the memory cells are required to be manufactured, and it serves to support and form the word-line holes 4 during the manufacturing of the memory array 1; whereas the support post 16 is formed in another region of the memory array 1 where the memory cell is not required to be manufactured, for example, the drain/source lead region, and it serves to support the memory array 1 during the manufacturing process. Of course, in other embodiments, the support post 16 may be arranged in the region of the memory array 1 where the memory cells are required to be manufactured. For example, when the distance between two adjacent isolation walls 3 is far, and the isolation wall 3 does not provide sufficient support, then the support post 16 may be arranged in this region as needed to assist the isolation wall 3 to provide support. That is, the support post 16 may be arranged according to the actual needs, which is not limited by the present disclosure.

The material of the support post 16 may be silicon oxide or silicon nitride.
Step S23: forming a storage structure on each of at least one side of a part of each word-line hole that exposes a corresponding drain region semiconductor strip, a corresponding channel semiconductor strip, and a corresponding source region semiconductor strip, where the storage structure is a charge trapping storage structure.

The product structure after processing by step S23 can be seen specifically in FIG. 26, which is a schematic view of the structure shown in FIG. 24b after processing by step S23. In some embodiments, step S23 specifically includes the following.
Step S231: depositing a first dielectric layer on the semiconductor substrate with the word-line holes 4.

Specifically, one layer of the first dielectric layer is deposited within each word-line hole 4 and on a surface of the first hard mask layer 83 back from the substrate 81. The first dielectric layer within each word-line hole 4 covers surfaces of the parts of the drain region semiconductor strips 11, channel semiconductor strips 12, and source region semiconductor strips 13 that are exposed on both sides of the word-line hole 4. For example, in conjunction with FIG. 4, parts of the first stacked structures 1b′ and the second stacked structures 1b′ are exposed through word-line hole 4 of the first row and the second column (hereinafter referred to as a first word-line hole 4), the first dielectric layer in the first word-line hole 4 covers the part of the first column of semiconductor strip storage structures 1b exposed through the first word-line hole 4, and the part of the second column of semiconductor strip structures 1b exposed through the first word-line hole 4.
Step S232: depositing a charge-trapping layer on the first dielectric layer.

The charge-trapping layer is disposed on a side surface of the first dielectric layer back from a corresponding semiconductor strip structure 1b.
Step S233: depositing a second dielectric layer on the charge-trapping layer.

The second dielectric layer is disposed on a side surface of the charge-trapping layer back from the first dielectric layer.

At block S24: filling each of the word-line holes with a gate material to form multiple gate strips.

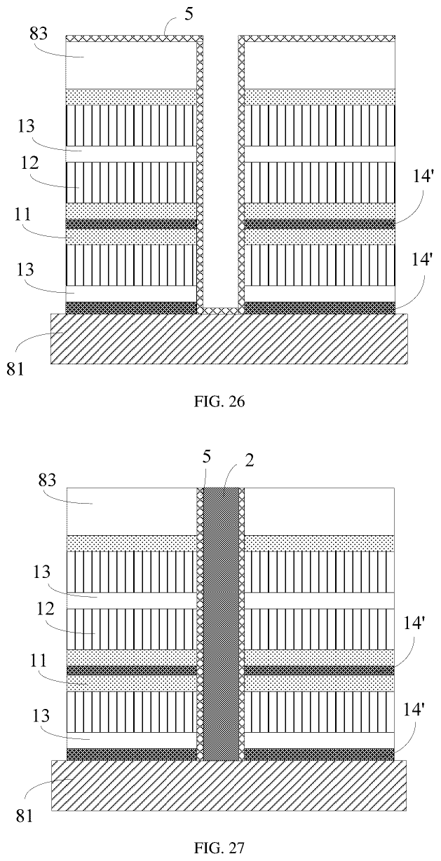

The product structure after processing by step S24 is specified in FIG. 5 and FIG. 27, where FIG. 27 is a schematic view of the structure shown in FIG. 26 after processing by step S24. As shown in FIG. 5, a projection of at least a part of each gate strip 2 coincides with a projection of a part of a corresponding channel semiconductor strip 12 in each memory subarray layer 1a on a projection plane extending along the height direction Z and the column direction Y. A part of the gate strip 2, a corresponding part of the channel semiconductor strip 12, a part of the drain region semiconductor strip 11 adjacent to the corresponding part of the channel semiconductor strip 12, a part of the source region semiconductor strip 13 adjacent to the corresponding part of the channel semiconductor strip 12, and a part of the charge trapping storage structure form a memory cell.

As above, in the embodiments, the storage structure 5 is a charge trapping storage structure, such as an ONO type charge trapping storage structure, such that it can hold the electric charges injected into near the injection point. The electric charges can only move in the injection/removal direction (substantially perpendicular to the extension direction of the charge-trapping layer 52), and cannot move freely in the charge-trapping layer 52, especially not in the extension direction of the charge-trapping layer 52. For the charge trapping storage structure, the charge-trapping layer 52 is only required to have an insulating dielectric arranged on its front and back side, and the charge stored in each memory cell will be fixed near the injection point of the charge-trapping portion and will not move to the charge-trapping portion in other memory cells along the same layer of the charge-trapping layer 52. Therefore, in its corresponding manufacturing method, it is only necessary to form a first dielectric layer 51 and a second dielectric layer 53 on both sides of the charge-trapping layer 52, respectively, to separate the charge-trapping layer 52 from the drain region semiconductor strip 11, the channel semiconductor strip 12, the source region semiconductor strip 13 and the gate strip 2, and its manufacturing method is relatively simple.

Specifically, the above manufacturing method of memory blocks may be configured to prepare the memory blocks involved in the following embodiments. In conjunction with FIG. 2a to FIG. 4, the memory block 10 includes a memory array 1, which includes multiple memory cells distributed in a three-dimensional array. The memory array 1 includes multiple stacked structures 1b′ distributed along the row direction X, each stacked structure 1b′ extending along the column direction Y, and each stacked structure 1b′ includes drain region semiconductor strips 11, channel semiconductor strips 12, and source region semiconductor strips 13 stacked along the height direction Z. Each drain region semiconductor strip 11, channel semiconductor strip 12, and source region semiconductor strip 13 extends along the column direction Y, and each drain region semiconductor strip 11, channel semiconductor strip 12, and source region semiconductor strip 13 is a single-crystal semiconductor strip.

Multiple gate strips 2 are arranged on each of two sides of each stacked structure 1b′ along the column direction Y, and each gate strip 2 extends along the height direction Z. In the height direction Z, a projection of at least a part of each gate strip 2 coincides with a projection of a part of a corresponding channel semiconductor strip 12 on a projection plane extending along the height direction Z and the column direction Y. A part of the gate strip 2, a corresponding part of the channel semiconductor strip 12, a part of the drain region semiconductor strip 11 adjacent to the corresponding part of the channel semiconductor strip 12, and a part of the source region semiconductor strip 13 adjacent to the corresponding part of the channel semiconductor strip 12 form a memory cell. Specifically, a charge trapping storage structure is arranged between each gate strip 2 and corresponding drain region semiconductor strips 11, channel semiconductor strips 12, and source region semiconductor strips 13 in the multiple stacked structures 1b′. The specific structure and function of the charge trapping storage structure, and the position relationship with the memory array 1, etc., can be found in the relevant description above.

Specifically, each stacked structure 1b′ includes multiple stacked substructures, each stacked substructure including a drain region semiconductor strip 11, a channel semiconductor strip 12, a source region semiconductor strip 13, a channel semiconductor strip 12, and a drain region semiconductor strip 11 stacked sequentially along the height direction Z to share the same source region semiconductor strip 13. Specifically, an interlayer isolation layer is arranged between two adjacent stacked substructures (i.e., the above-mentioned insulating isolation layer 14′) to isolate the two adjacent stacked substructures from each other.

Multiple isolation walls 3 distributed along the column direction Y are arranged on each side of each stacked structure 1b′, and each isolation wall 3 extends along the height direction Z and the row direction X to separate at least part of the two adjacent columns of the stacked structures 1b′. The isolation walls 3 further serve as support structures to support the two adjacent columns of the stacked structures 1b′ in the manufacturing process as shown above to facilitate the subsequent manufacturing process. Of course, after the manufacturing process, the isolation walls 3 may be further configured as support structures to support the two adjacent columns of the stacked structures 1b′. The isolation wall 3 near an edge of the memory block 10 in the column direction Y is a T-shaped wall to completely isolate the two adjacent columns of the stacked structures 1b′. Of course, the isolation wall 3 at the edge in the column direction Y may take other shapes, such as extending in the column direction Y to the edge of the memory block 10 in the column direction Y, etc., as long as it can completely isolate the two adjacent columns of the stacked structures 1b′ at the edge of the memory block 10 in the column direction Y.

In the column direction Y, a gate strip 2 is arranged between two adjacent isolation walls 3 on the same column; parts of two adjacent columns of the stacked structures 1b share the same gate strip 2.

Other structures and functions of the memory block 10 provided in the embodiments can be found in the specific description of the memory block 10 provided in any of the above embodiments where the storage structure is a charge trapping storage structure, and will not be repeated herein.

The memory cell corresponding to the above manufacturing method includes: a drain region portion 11′, a channel portion 12′, a source region portion 13′, and a gate portion 2′. The drain region portion 11′, the channel portion 12′, and the source region portion 13′ are stacked along the height direction Z, and the gate portion 2′ is disposed on one side of the drain region portion 11′, the channel portion 12′, and the source region portion 13′, and along the height direction Z. In the height direction Z, a projection of the gate portion 2′ at least partially coincides with a projection of the channel portion 12′ on a projection plane, the projection plane extending along the height direction Z and the drain region portion 11′. A charge trapping storage structure portion is arranged between the gate portion 2′ and the drain region portion 11′, the channel portion 12′, and the source region portion 13′.

The specific structure and position of the charge trapping storage structure portion can be found in the above description. Other structures and functions of the memory cell can be found in the description of the memory cell with the charge trapping storage structure portion 5′ involved in the above embodiments, which will not be repeated herein.

The above is only some embodiments of the present disclosure, and is not intended to limit the scope of the present disclosure. Any equivalent structure or equivalent process transformation using the contents and the accompanying drawings of the present disclosure, or any direct or indirect application in other related technical fields, is included in the scope of the present disclosure.

1. A manufacturing method of a memory block, comprising:
providing a semiconductor substrate, wherein the semiconductor substrate comprises a substrate and a plurality of memory subarray layers formed on the substrate, the memory subarray layers are sequentially stacked along a height direction perpendicular to the substrate, and each memory subarray layer comprises a drain region semiconductor layer, a channel semiconductor layer, and a source region semiconductor layer stacked along the height direction;
forming a plurality of word-line holes on the semiconductor substrate to divide each memory subarray layer into a plurality of columns of drain region semiconductor strips, channel semiconductor strips, and source region semiconductor strips along a row direction, wherein the word-line holes are arranged in a matrix in the row direction and a column direction, each word-line hole extends along the height direction, and at least one side of each word-line hole exposes parts of at least one column of drain region semiconductor strips, channel semiconductor strips, and source region semiconductor strips of the memory subarray layers;
forming a storage structure on each of at least one side of a part of each word-line hole that exposes a corresponding drain region semiconductor strip, a corresponding channel semiconductor strip, and a corresponding source region semiconductor strip, wherein the storage structure is a charge trapping storage structure;
filling each word-line hole with a gate material to form a plurality of gate strips, wherein a projection of at least a part of each gate strip coincides with a projection of a part of a corresponding channel semiconductor strip in each memory subarray layer on a projection plane, the projection plane extends along the height direction and the column direction, and a part of the gate strip, a corresponding part of the channel semiconductor strip, a part of the charge trapping storage structure interposed between the part of the gate strip and the corresponding part of the channel semiconductor strip, and a part of the drain region semiconductor strip and a part of the source region semiconductor strip adjacent to the corresponding part of the channel semiconductor strip are configured to form a memory cell.

2. The manufacturing method according to claim 1, wherein the providing a semiconductor substrate, comprises:
providing the substrate;
forming the plurality of memory subarray layers sequentially on the substrate along the height direction;
forming a first hard mask layer on the memory subarray layers, forming a plurality of isolation wall holes in the first hard mask layer and the memory subarray layers, and filling the isolation wall holes with an isolation material to form a plurality of isolation walls to form the semiconductor substrate, wherein the isolation wall holes are arranged in a matrix in the row direction and the column direction, and each isolation wall hole extends along the height direction to a surface of the substrate.

3. The manufacturing method according to claim 2, wherein the substrate is a single-crystal substrate, and the forming the plurality of memory subarray layers sequentially on the substrate along the height direction, comprises:
forming a first single-crystal sacrificial semiconductor layer or a dummy memory subarray layer on the substrate by epitaxial growth;
forming two memory subarray layers and a second single-crystal sacrificial semiconductor layer on the first single-crystal sacrificial semiconductor layer by epitaxial growth alternately in sequence until uppermost two memory subarray layers are formed; or forming a second single-crystal sacrificial semiconductor layer and two memory subarray layers on the dummy memory subarray layer by epitaxial growth alternately in sequence.

4. The manufacturing method according to claim 3, wherein two adjacent memory subarray layers share a common source region, and a manufacturing method of each two adjacent memory subarray layers sharing the common source region comprises:
forming a first single-crystal semiconductor layer of a first doping type on the first single-crystal sacrificial semiconductor layer or the second single-crystal sacrificial semiconductor layer by epitaxial growth;
forming a second single-crystal semiconductor layer of a second doping type on the first single-crystal semiconductor layer by epitaxial growth;
forming a third single-crystal semiconductor layer of the first doping type on the second single-crystal semiconductor layer by epitaxial growth;
forming a fourth single-crystal semiconductor layer of the second doping type on the third single-crystal semiconductor layer by epitaxial growth;
forming a fifth single-crystal semiconductor layer of the first doping type on the fourth single-crystal semiconductor layer by epitaxial growth;
wherein the first single-crystal semiconductor layer and the fifth single-crystal semiconductor layer of the first doping type are configured to serve as the drain region semiconductor layers, the second single-crystal semiconductor layer and the fourth single-crystal semiconductor layer of the second doping type are configured to serve as the channel semiconductor layers, and the third single-crystal semiconductor layer of the first doping type is configured to serve as the source region semiconductor layer;
the first single-crystal semiconductor layer, the second single-crystal semiconductor layer, and the third single-crystal semiconductor layer form a memory subarray layer; the third single-crystal semiconductor layer, the fourth single-crystal semiconductor layer, and the fifth single-crystal semiconductor layer form another memory subarray layer; and two memory subarray layers share the third single-crystal semiconductor layer as a shared source region semiconductor layer.

5. The manufacturing method according to claim 3, wherein the forming a plurality of word-line holes on the semiconductor substrate, comprises:
forming a plurality of word-line openings on the first hard mask layer, wherein the word-line openings are arranged in a matrix in the row direction and the column direction;
etching the memory subarray layers under the first hard mask layer to form the word-line holes by using the first hard mask layer with the word-line openings as a hard mask, wherein the word-line holes together with the isolation walls divide each memory subarray layer into columns of drain region semiconductor strips, channel semiconductor strips, and source region semiconductor strips along the row direction.

6. The manufacturing method according to claim 5, further comprising:
removing the first single-crystal sacrificial semiconductor layer and the second single-crystal sacrificial semiconductor layer through the word-line holes;
depositing on regions where a removed first single-crystal sacrificial semiconductor layer and second single-crystal sacrificial semiconductor layer is located to fill the regions where the removed first single-crystal sacrificial semiconductor layer and second single-crystal sacrificial semiconductor layer is located with an insulating material, thereby replacing the first single-crystal sacrificial semiconductor layer and the second single-crystal sacrificial semiconductor layer with an insulating isolation layer.

7. The manufacturing method according to claim 1, wherein the forming a storage structure on each of at least one side of a part of each word-line hole that exposes a corresponding drain region semiconductor strip, a corresponding channel semiconductor strip, and a corresponding source region semiconductor strip, comprises:
depositing a first dielectric layer on the semiconductor substrate with the word-line holes, wherein the first dielectric layer covers parts of the drain region semiconductor strips, channel semiconductor strips, and source region semiconductor strips that are exposed on both sides of the word-line holes;
depositing a charge-trapping layer on the first dielectric layer;
depositing a second dielectric layer on the charge-trapping layer.

8. The manufacturing method according to claim 7, wherein the filling each word-line hole with a gate material to form a plurality of gate strips, comprises:
filling each word-line hole with the gate material respectively to form the gate strips, wherein the charge trapping storage structure is arranged between each gate strip and corresponding drain region semiconductor strips, channel semiconductor strips, and source region semiconductor strips in the memory subarray layers.

9. A memory block, comprising:
a memory array, comprising a plurality of memory cells distributed in a three-dimensional array, wherein the memory array comprises a plurality of stacked structures distributed along a row direction, each stacked structure extends along a column direction; each stacked structure comprises drain region semiconductor strips, channel semiconductor strips, and source region semiconductor strips stacked along a height direction, each drain region semiconductor strip, channel semiconductor strip, and source region semiconductor strip extends along the column direction; a plurality of gate strips spaced along the column direction are arranged on each of two sides of each stacked structure, and each gate strip extends along the height direction;
in the height direction, a projection of at least a part of each gate strip coincides with a projection of a part of a corresponding channel semiconductor strip on a projection plane, and the projection plane extends along the height direction and the column direction; a part of the gate strip, a corresponding part of the channel semiconductor strip, a part of the drain region semiconductor strip adjacent to the corresponding part of the channel semiconductor strip, and a part of the source region semiconductor strip adjacent to the corresponding part of the channel semiconductor strip are configured to form a memory cell;
a charge trapping storage structure is arranged between each gate strip and the drain region semiconductor strips, channel semiconductor strips, and source region semiconductor strips of the plurality of stacked structures.

10. The memory block according to claim 9, wherein each drain region semiconductor strip, channel semiconductor strip, and source region semiconductor strip is a single-crystal semiconductor strip, respectively.

11. The memory block according to claim 9, wherein each stacked structure comprises a plurality of stacked substructures, and each stacked substructure comprises a drain region semiconductor strip, a channel semiconductor strip, a source region semiconductor strip, a channel semiconductor strip, and a drain region semiconductor strip stacked sequentially along the height direction to share the same source region semiconductor strip.

12. The memory block according to claim 11, wherein an interlayer isolation strip is arranged between two adjacent stacked substructures to isolate them from each other.

13. The memory block according to claim 9, wherein a plurality of isolation walls distributed along the column direction are arranged on each of the two sides of each stacked structure, and each isolation wall extends along the height direction and the row direction to separate at least parts of the two adjacent columns of stacked structures.

14. The memory block according to claim 13, wherein in the column direction, a gate strip is arranged between two adjacent isolation walls on the same column; parts of the two adjacent columns of stacked structures share the same gate strip.

15. The memory block according to claim 13, wherein the isolation wall near an edge of the memory block in the column direction extends along the column direction to the edge of the memory block in the column direction, to completely isolate the two adjacent columns of stacked structures.

16. The memory block according to claim 9, wherein the charge trapping storage structure comprises a first dielectric layer, a charge-trapping layer, and a second dielectric layer, the first dielectric layer is disposed between the charge-trapping layer and the stacked structure, the charge-trapping layer is disposed between the first dielectric layer and the second dielectric layer, and the second dielectric layer is disposed between the charge-trapping layer and the gate strip.

17. The memory block according to claim 9, wherein
two adjacent columns of gate strips are distributed in a staggered manner in the row direction; or
two adjacent columns of gate strips are aligned in the row direction.

18. A memory cell, comprising:
a drain region portion, a channel portion, a source region portion, and a gate portion, wherein the drain region portion, the channel portion, and the source region portion are stacked along a height direction, and the gate portion is disposed on one side of the drain region portion, the channel portion, and the source region portion, and extends along the height direction;
in the height direction, a projection of the gate portion at least partially overlaps with a projection of the channel portion on a projection plane, the projection plane extends along the height direction and an extension direction of the drain region portion, the channel portion, and the source region portion, and a charge trapping storage structure portion is arranged between the gate portion and the drain region portion, the channel portion, and the source region portion.

19. The memory cell according to claim 18, wherein the drain region portion, the channel portion, and the source region portion are each a single-crystal semiconductor.

20. The memory cell according to claim 18, wherein the charge trapping storage structure portion comprises a first dielectric portion, a charge-trapping portion, and a second dielectric portion, the first dielectric portion is disposed between the charge-trapping portion and adjacent drain region portion, channel portion, and source region portion, the charge-trapping portion is disposed between the first dielectric portion and the second dielectric portion, and the second dielectric portion is disposed between the charge-trapping portion and the gate portion.
